(19) United States
(12) Patent Application Publication
(10) Pub. No.: US 2025/0221070 A1
(43) Pub. Date: Jul. 3, 2025

(54) IMAGING DEVICE AND SEMICONDUCTOR DEVICE

(71) Applicant: SONY SEMICONDUCTOR SOLUTIONS CORPORATION, KANAGAWA (JP)

(72) Inventors: SUSUMU TONEGAWA, KANAGAWA (JP); SHINTARO OKAMOTO, KANAGAWA (JP)

(21) Appl. No.: 18/849,975

(22) PCT Filed: Mar. 16, 2023
(86) PCT No.: PCT/JP2023/010347

§ 371 Date: Sep. 23, 2024

(30) Foreign Application Priority Data
Mar. 31, 2022 (JP) 2022-059177

(51) Int. Cl. H10F 39/00

(52) U.S. Cl. CPC H10F 39/80377; H10F 39/018; H10F 39/809; H10F 39/811

(57) ABSTRACT

There is provided an imaging device and a semiconductor device capable of suppressing deterioration of characteristics of pixel transistors (alternatively, transistors) provided in a second semiconductor layer due to electromagnetic interference from a first semiconductor layer side. An imaging device includes a first semiconductor layer provided with a sensor pixel that performs photoelectric conversion, a second semiconductor layer disposed on one surface side of the first semiconductor layer and provided with a pixel transistor for outputting a pixel signal based on a charge output from the sensor pixel, an insulating layer disposed between the first semiconductor layer and the second semiconductor layer, and a conductor layer disposed between the sensor pixel and the pixel transistor in the insulating layer. A potential of the conductor layer is fixed to a reference potential.

### TECHNICAL FIELD

The present disclosure relates to an imaging device and a semiconductor device.

### BACKGROUND ART

In order to implement further miniaturization of an imaging device and densification of pixels, an imaging device having a three-dimensional structure has been developed. In the imaging device having a three-dimensional structure, for example, a first semiconductor substrate having a plurality of sensor pixels and a second semiconductor substrate having a signal processing circuit for processing a signal obtained by each sensor pixel are stacked on each other (see, for example, Patent Document 1).

### CITATION LIST

### Patent Document

Patent Document 1: WO 2019/131965 A1

### SUMMARY OF THE INVENTION

### Problems to be Solved by the Invention

In order to further miniaturize the imaging device having a three-dimensional structure, a structure in which a wiring layer is disposed on a surface side facing the second semiconductor substrate in the first semiconductor substrate is considered. When a voltage is applied to the wiring layer, the voltage may interfere with characteristics of pixel transistors disposed on the second semiconductor substrate, and the characteristics of the pixel transistors may fluctuate.

The present disclosure has been made in view of such circumstances, and an object thereof is to provide an imaging device and a semiconductor device capable of suppressing deterioration of characteristics of pixel transistors (alternatively, transistors) provided in a second semiconductor layer due to electromagnetic interference from a first semiconductor layer side.

### Solutions to Problems

An imaging device according to an aspect of the present disclosure includes a first semiconductor layer provided with a sensor pixel that performs photoelectric conversion, a second semiconductor layer disposed on one surface side of the first semiconductor layer and provided with a pixel transistor for outputting a pixel signal based on a charge output from the sensor pixel, an insulating layer disposed between the first semiconductor layer and the second semiconductor layer, and a conductor layer disposed between the sensor pixel and the pixel transistor in the insulating layer. A potential of the conductor layer is fixed to a reference potential.

With this configuration, the conductor layer can electromagnetically block between the sensor pixel provided in the first semiconductor layer and the pixel transistor provided in the second semiconductor layer, and can suppress electromagnetic interference from the sensor pixel side to the pixel transistor. For example, the sensor pixel includes a photoelectric conversion element that performs photoelectric conversion, and a transfer transistor for transferring a charge generated in the photoelectric conversion element. In a case where the wiring layer connected to a gate electrode (that is, a transfer gate) of the transfer transistor is disposed between the photoelectric conversion element and the conductor layer, the conductor layer can suppress bias interference from the wiring layer to the pixel transistor.

Thus, it is possible to suppress deterioration of characteristics (for example, noise characteristics) of the pixel transistor provided in the second semiconductor layer due to electromagnetic interference from the first semiconductor layer side.

A semiconductor device according to an aspect of the present disclosure includes a first semiconductor layer, a second semiconductor layer disposed on one surface side of the first semiconductor layer and provided with a transistor, an insulating layer disposed between the first semiconductor layer and the second semiconductor layer, and a conductor layer disposed between the first semiconductor layer and the transistor in the insulating layer. A potential of the conductor layer is fixed to a reference potential.

With this configuration, the conductor layer can electromagnetically block between the first semiconductor layer and the transistor provided in the second semiconductor layer, and can suppress electromagnetic interference from the first semiconductor layer side to the transistor. Thus, it is possible to suppress deterioration of characteristics (for example, noise characteristics) of the transistor provided in the second semiconductor layer.

### BRIEF DESCRIPTION OF DRAWINGS

FIG. 1 is a schematic diagram illustrating a configuration example of an imaging device according to a first embodiment of the present disclosure.

FIG. 2 illustrates an example of a sensor pixel and a readout circuit.

FIG. 3 is a cross-sectional view illustrating a configuration example of the imaging device according to the first embodiment of the present disclosure.

FIG. 4 is a plan view illustrating a configuration example of the imaging device according to the first embodiment of the present disclosure.

FIG. 5 is a cross-sectional view of the imaging device illustrated in FIG. 3 taken along a horizontal plane orthogonal to a thickness direction of the imaging device.

FIG. 6 is a cross-sectional view of the imaging device illustrated in FIG. 3 taken along a horizontal plane orthogonal to the thickness direction of the imaging device.

FIG. 7 is a cross-sectional view of the imaging device illustrated in FIG. 3 taken along a horizontal plane orthogonal to the thickness direction of the imaging device.

FIG. 8A is a cross-sectional view illustrating a method for manufacturing the imaging device according to the first embodiment of the present disclosure in order of steps.

FIG. 8B is a cross-sectional view illustrating the method for manufacturing the imaging device according to the first embodiment of the present disclosure in order of steps.

FIG. 8C is a cross-sectional view illustrating the method for manufacturing the imaging device according to the first embodiment of the present disclosure in order of steps.

FIG. 8D is a cross-sectional view illustrating the method for manufacturing the imaging device according to the first embodiment of the present disclosure in order of steps.

FIG. 8E is a cross-sectional view illustrating the method for manufacturing the imaging device according to the first embodiment of the present disclosure in order of steps.

FIG. 8F is a cross-sectional view illustrating the method for manufacturing the imaging device according to the first embodiment of the present disclosure in order of steps.

FIG. 8G is a cross-sectional view illustrating the method for manufacturing the imaging device according to the first embodiment of the present disclosure in order of steps.

FIG. 8H is a cross-sectional view illustrating the method for manufacturing the imaging device according to the first embodiment of the present disclosure in order of steps.

FIG. 8I is a cross-sectional view illustrating the method for manufacturing the imaging device according to the first embodiment of the present disclosure in order of steps.

FIG. 8J is a cross-sectional view illustrating the method for manufacturing the imaging device according to the first embodiment of the present disclosure in order of steps.

FIG. 8K is a cross-sectional view illustrating the method for manufacturing the imaging device according to the first embodiment of the present disclosure in order of steps.

FIG. 9 is a cross-sectional view illustrating a configuration example of an imaging device according to a second embodiment of the present disclosure.

FIG. 10 is a plan view illustrating a configuration example of the imaging device according to the second embodiment of the present disclosure.

FIG. 11 is a cross-sectional view of the imaging device illustrated in FIG. 9 taken along a horizontal plane orthogonal to the thickness direction thereof.

FIG. 12 is a cross-sectional view of the imaging device illustrated in FIG. 9 taken along a horizontal plane orthogonal to the thickness direction thereof.

FIG. 13 is a cross-sectional view of the imaging device illustrated in FIG. 9 taken along a horizontal plane orthogonal to the thickness direction thereof.

FIG. 14 is a plan view illustrating an imaging device according to a modification of the second embodiment of the present disclosure.

FIG. 15 is a plan view illustrating a second wiring layer 18 of an imaging device according to a modification of the second embodiment of the present disclosure.

FIG. 16 is a cross-sectional view illustrating a configuration example of an imaging device according to a third embodiment of the present disclosure.

FIG. 17A is a cross-sectional view illustrating a method for manufacturing the imaging device according to the third embodiment of the present disclosure in order of steps.

FIG. 17B is a cross-sectional view illustrating the method for manufacturing the imaging device according to the third embodiment of the present disclosure in order of steps.

FIG. 17C is a cross-sectional view illustrating the method for manufacturing the imaging device according to the third embodiment of the present disclosure in order of steps.

FIG. 17D is a cross-sectional view illustrating the method for manufacturing the imaging device according to the third embodiment of the present disclosure in order of steps.

FIG. 17E is a cross-sectional view illustrating the method for manufacturing the imaging device according to the third embodiment of the present disclosure in order of steps.

FIG. 17F is a cross-sectional view illustrating the method for manufacturing the imaging device according to the third embodiment of the present disclosure in order of steps.

FIG. 17G is a cross-sectional view illustrating the method for manufacturing the imaging device according to the third embodiment of the present disclosure in order of steps.

FIG. 17H is a cross-sectional view illustrating the method for manufacturing the imaging device according to the third embodiment of the present disclosure in order of steps.

FIG. 17I is a cross-sectional view illustrating the method for manufacturing the imaging device according to the third embodiment of the present disclosure in order of steps.

FIG. 17J is a cross-sectional view illustrating the method for manufacturing the imaging device according to the third embodiment of the present disclosure in order of steps.

FIG. 17K is a cross-sectional view illustrating the method for manufacturing the imaging device according to the third embodiment of the present disclosure in order of steps.

FIG. 17L is a cross-sectional view illustrating the method for manufacturing the imaging device according to the third embodiment of the present disclosure in order of steps.

FIG. 17M is a cross-sectional view illustrating the method for manufacturing the imaging device according to the third embodiment of the present disclosure in order of steps.

FIG. 17N is a cross-sectional view illustrating the method for manufacturing the imaging device according to the third embodiment of the present disclosure in order of steps.

FIG. 18 is a plan view illustrating a configuration example of a pixel transistor having an FD SOI Fin structure according to a fourth embodiment of the present disclosure.

FIG. 19 is a cross-sectional view illustrating a configuration example of the pixel transistor having the FD SOI Fin structure according to the fourth embodiment of the present disclosure.

FIG. 20 is a cross-sectional view illustrating a configuration example of the pixel transistor having the FD SOI Fin structure according to the fourth embodiment of the present disclosure.

FIG. 21 is a cross-sectional view illustrating a configuration example of the pixel transistor having the FD SOI Fin structure according to the fourth embodiment of the present disclosure.

FIG. 22 is a diagram illustrating a cross-sectional configuration example of an imaging device according to a fifth embodiment of the present disclosure.

FIG. 23 is a block diagram illustrating an example of a schematic configuration of a vehicle control system.

FIG. 24 is an explanatory view illustrating an example of installation positions of an outside-vehicle information detecting section and an imaging section.

FIG. 25 is a diagram illustrating an example of a schematic configuration of an endoscopic surgery system to which the technology according to the present disclosure (present technology) can be applied.

FIG. 26 is a block diagram illustrating an example of a functional configuration of a camera head and a camera control unit (CCU) illustrated in FIG. 25.

### MODE FOR CARRYING OUT THE INVENTION

Hereinafter, an embodiment of the present disclosure is described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it goes without saying that dimensional relationships and ratios are partly different between the drawings.

Furthermore, the definitions of directions such as up and down or the like in the following description are merely definitions for convenience of description, and do not limit the technical idea of the present disclosure. For example, it is a matter of course that when an object is observed by rotating the object by 90°, the up and down are converted into and read as left and right, and when the object is observed by rotating the object by 180°, the up and down are inverted and read.

Furthermore, in the following description, the direction is sometimes described using terms such as an X-axis direction, a Y-axis direction, and a Z-axis direction. For example, the Z-axis direction is a thickness direction of a semiconductor substrate 11 to be described later, and is a normal direction of a front surface 11a of the semiconductor substrate 11. The X-axis direction and the Y-axis direction are directions orthogonal to the Z-axis direction. The X-axis direction, the Y-axis direction, and the Z-axis direction are orthogonal to each other. Furthermore, in the following description, “plan view” means viewing from the Z-axis direction.

### First Embodiment

### Configuration

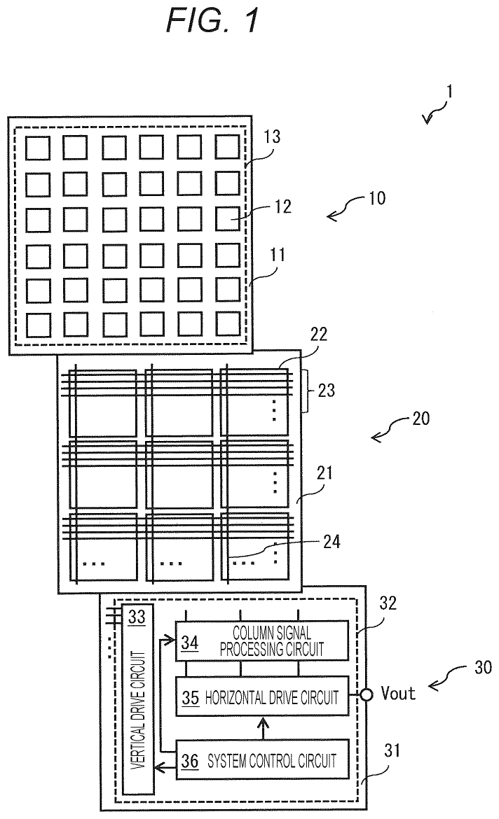

FIG. 1 is a schematic diagram illustrating a configuration example of an imaging device 1 according to a first embodiment of the present disclosure. The imaging device 1 includes three substrates (first substrate 10, second substrate 20, and third substrate 30). The imaging device 1 is an imaging device having a three-dimensional structure formed by bonding three substrates (first substrate 10, second substrate 20, and third substrate 30). The first substrate 10, the second substrate 20, and the third substrate 30 are stacked in this order.

The first substrate 10 includes a plurality of sensor pixels 12 that performs photoelectric conversion on the semiconductor substrate 11 (an example of a “first semiconductor layer” of the present disclosure). The plurality of sensor pixels 12 is provided in a matrix in the pixel region 13 of the first substrate 10.

The second substrate 20 includes, on a semiconductor substrate 21 (an example of the “second semiconductor layer” of the present disclosure), readout circuits 22 that output pixel signals based on electric charges output from the sensor pixels 12, each of the readout circuits 22 being provided for the four sensor pixels 12. The second substrate 20 includes a plurality of pixel drive lines 23 extending in the row direction and a plurality of vertical signal lines 24 extending in the column direction.

The third substrate 30 includes a logic circuit 32 that processes a pixel signal on a semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each sensor pixel 12 to the outside. In the logic circuit 32, a low-resistance region, which is made from a silicide formed by using a self aligned silicide (salicide) process such as CoSi₂ or NiSi, may be formed on, for example, a front surface of an impurity diffusion region that is in contact with a source electrode and a drain electrode.

The vertical drive circuit 33 sequentially selects the plurality of sensor pixels 12 row by row, for example. The column signal processing circuit 34 performs, for example, correlated double sampling (CDS) processing on the pixel signal output from each sensor pixel 12 in the row selected by the vertical drive circuit 33. The column signal processing circuit 34 extracts a signal level of a pixel signal by performing CDS processing, for example, and holds pixel data corresponding to the amount of light received by each sensor pixel 12. The horizontal drive circuit 35 sequentially outputs the pixel data held in the column signal processing circuit 34 to the outside, for example. The system control circuit 36 controls driving of each block (vertical drive circuit 33, column signal processing circuit 34, and horizontal drive circuit 35) in the logic circuit 32, for example.

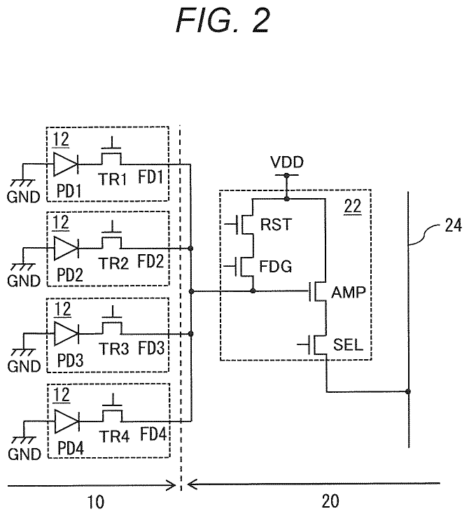

FIG. 2 illustrates an example of the sensor pixel 12 and the readout circuit 22. Hereinafter, as illustrated in FIG. 2, a case where four sensor pixels 12 share one readout circuit 22 will be described. Here, “sharing” means that the outputs of the four sensor pixels 12 are input to the common readout circuit 22.

Each sensor pixel 12 has a common component. In FIG. 2, identification numbers (1,2, 3, and 4) are added to the ends of the signs of the components of the sensor pixels 12 in order to distinguish the components of the sensor pixels 12 from each other. In the following, in a case where it is necessary to distinguish the components of each sensor pixel 12 from each other, the identification number is attached to the end of the reference sign of the component of each sensor pixel 12, but in a case where it is not necessary to distinguish the components of each sensor pixel 12 from each other, the identification number at the end of the reference sign of the component of each sensor pixel 12 is omitted.

Each sensor pixel 12 includes, for example, a photodiode PD (an example of a “photoelectric conversion element” of the present disclosure), a transfer transistor TR electrically connected to the photodiode PD, and a floating diffusion FD that temporarily holds the charge output from the photodiode PD via the transfer transistor TR. The photodiode PD generates electric charge corresponding to an amount of received light by photoelectric conversion. A cathode of the photodiode PD is electrically connected to a source of the transfer transistor TR, and an anode of the photodiode PD is electrically connected to a reference potential line (for example, ground). A drain of the transfer transistor TR is electrically connected to the floating diffusion FD, and a gate of the transfer transistor TR is electrically connected to the pixel drive line 23. The transfer transistor TR is, for example, a complementary metal oxide semiconductor (CMOS) transistor.

The floating diffusions FD of the sensor pixels 12 sharing one readout circuit 22 are electrically connected to each other and are electrically connected to an input end of the common readout circuit 22. The readout circuit 22 includes, for example, a reset transistor RST, a selection transistor SEL, and an amplification transistor AMP. Note that the selection transistor SEL may be omitted as necessary. A source of the reset transistor RST (the input end of the readout circuit 22) is electrically connected to the floating diffusion FD, and a drain of the reset transistor RST is electrically connected to a power supply line VDD and a drain of the amplification transistor AMP. A gate of the reset transistor RST is electrically connected to the pixel drive line 23 (see FIG. 1). A source of the amplification transistor AMP is electrically connected to a drain of the selection transistor SEL, and a gate of the amplification transistor AMP is electrically connected to the source of the reset transistor RST. A source of the selection transistor SEL (the output end of the readout circuit 22) is electrically connected to the vertical signal line 24, and a gate of the selection transistor SEL is electrically connected to the pixel drive line 23 (see FIG. 1).

The transfer transistor TR transfers electric charges of the photodiode PD to the floating diffusion FD when turned on. The reset transistor RST resets a potential of the floating diffusion FD to a predetermined potential. The reset transistor RST resets the potential of the floating diffusions FD to a potential of the power supply line VDD when turned on. The selection transistor SEL controls the output timing of the pixel signal from the readout circuit 22. The amplification transistor AMP generates a signal of a voltage corresponding to the level of the electric charges held in the floating diffusion FD as a pixel signal. The amplification transistor AMP constitutes a source follower type amplifier, and outputs a pixel signal having a voltage corresponding to the level of the electric charges generated in the photodiode PD. When the selection transistor SEL is turned on, the amplification transistor AMP amplifies the potential of the floating diffusion FD, and outputs a voltage corresponding to the potential to the column signal processing circuit 34 via the vertical signal line 24. The reset transistor RST, the amplification transistor AMP, and the selection transistor SEL are, for example, CMOS transistors.

The source of the amplification transistor AMP (the output end of the readout circuit 22) is electrically connected to the vertical signal line 24, a switch transistor FDG is provided between the source of the reset transistor RST and the gate of the amplification transistor AMP, and the gate of the amplification transistor AMP is electrically connected to a source of the switch transistor FDG.

The switch transistor FDG is used to switch the conversion efficiency. In a case where a gate of the switch transistor FDG is turned off, the floating diffusion FD is disconnected from the source and drain of the reset transistor RST, and thus has a small capacitance. Since the floating diffusion FD has a small capacitance, the potential greatly decreases with a small number of electrons, and a highly sensitive signal is output. However, when there are many signal electrons, the floating diffusion FD overflows, so that it is not possible to obtain an original signal according to the incident amount. In a case where the gate of the switch transistor FDG is turned on, the floating diffusion FD is connected to the source and drain of the reset transistor RST, and has a large capacitance. Since the capacity increases, instead of receiving many electrons, the sensitivity decreases. As described above, by switching the gate of the switch transistor FDG, it is possible to obtain an image from which charges are read in the high-sensitivity operation mode and an image from which charges are read in the low-sensitivity operation mode, and by combining the obtained images, it is possible to expand the dynamic range.

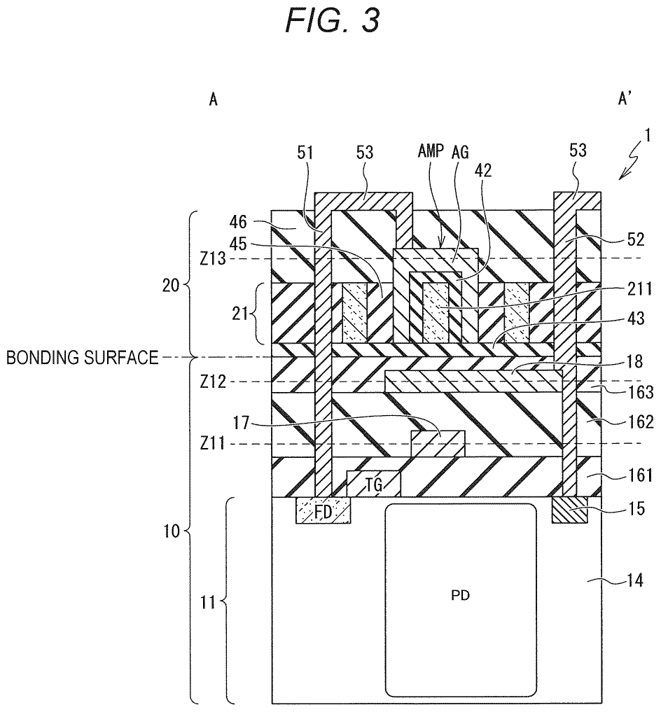

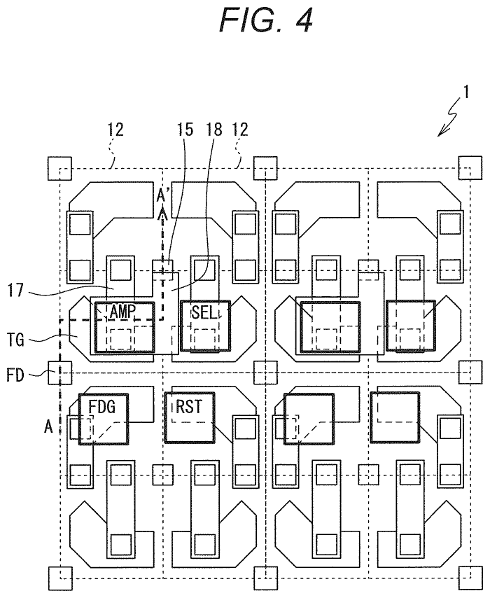

FIG. 3 is a cross-sectional view illustrating a configuration example of the imaging device 1 according to the first embodiment of the present disclosure. FIG. 4 is a plan view illustrating a configuration example of the imaging device 1 according to the first embodiment of the present disclosure. FIG. 3 illustrates a cross section obtained by cutting the plan view illustrated in FIG. 4 along line A-A′, and illustrates a cross section of a stack including the first substrate 10 and the second substrate 20.

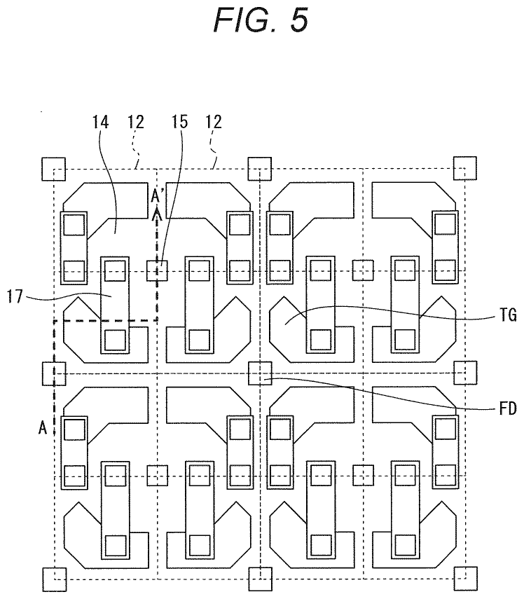

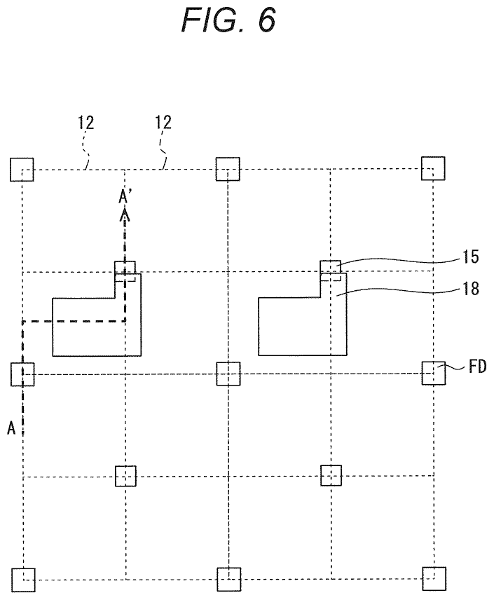

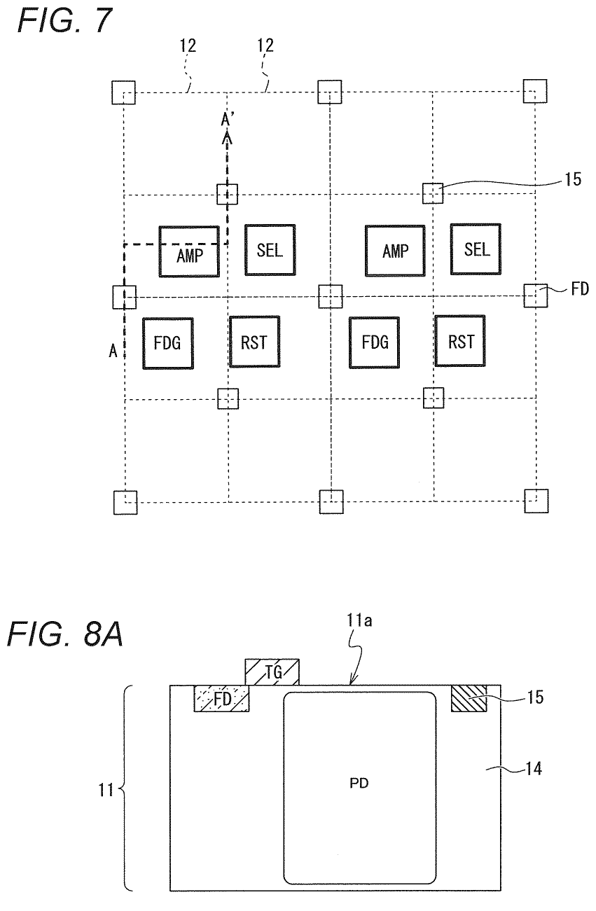

FIGS. 5 to 7 are cross-sectional views of the imaging device 1 illustrated in FIG. 3 taken along a horizontal plane orthogonal to the thickness direction thereof. More specifically, FIG. 5 illustrates a cross section taken along a horizontal plane Z11 passing through a first wiring layer 17. FIG. 6 illustrates a cross section taken along a horizontal plane Z12 passing through a second wiring layer 18. FIG. 7 illustrates a cross section taken along a horizontal plane Z13 passing through a gate electrode AG of the amplification transistor AMP.

Note that a view in which the cross-sectional views of FIGS. 5 to 7 are aligned and superimposed corresponds to FIG. 4. Furthermore, in FIGS. 4 to 7, illustration of a first insulating film 161, a second insulating film 162, a third insulating film 163, a fourth insulating film 164, a fifth insulating film 45, a sixth insulating film 46, through wirings 51 and 52, and a third wiring layer 53 illustrated in FIG. 3 is omitted. In FIGS. 4 and 7, the reset transistor RST, the switch transistor FDG, the amplification transistor AMP, and the selection transistor SEL are schematically illustrated by rectangles. Each of the reset transistor RST, the switch transistor FDG, the amplification transistor AMP, and the selection transistor SEL is also referred to as a pixel transistor.

As illustrated in FIG. 3, in the imaging device 1 according to the first embodiment, the semiconductor substrate 11 of the first substrate 10 is provided with the photodiode PD, a well region 14 in which a channel of the transfer transistor TR is formed, a well contact region 15 connected to the well region 14, and the floating diffusion FD corresponding to a drain of the transfer transistor TR. The photodiode PD includes, for example, an N-type impurity diffusion layer and a P-type impurity diffusion layer having a PN junction with the N-type impurity diffusion layer. The well region 14 and the well contact region 15 are, for example, P-type impurity diffusion layers. The well contact region 15 has a higher P-type impurity concentration than the well region 14. The floating diffusion FD is an N-type impurity diffusion layer. Furthermore, a transfer gate TG, which is a gate electrode of the transfer transistor TR, is provided on the semiconductor substrate 11 via a gate insulating film.

The first insulating film 161 is provided on the semiconductor substrate 11. The transfer gate TG is covered with the first insulating film 161. The first wiring layer 17 and the second insulating film 162 are provided on the first insulating film 161. The first wiring layer 17 is covered with the second insulating film 162. Furthermore, the second wiring layer 18 (an example of a “conductor layer” in the present disclosure) and third insulating film 163 are provided on the second insulating film 162. The second wiring layer 18 is covered with the third insulating film 163.

The second substrate 20 is bonded to the first substrate 10. For example, the third insulating film 163 of the first substrate 10 and a fourth insulating film 43 of the second substrate 20 are bonded together. The fourth insulating film 43 is constituted by, for example, a silicon oxide film (SiO₂ film).

As illustrated in FIGS. 3 and 4, the second substrate 20 is provided with a reset transistor RST, a switch transistor FDG, an amplification transistor AMP, and a selection transistor SEL. As illustrated in FIG. 3, the amplification transistor AMP includes a semiconductor layer 211 serving as a channel region, a gate electrode AG covering the semiconductor layer 211, and a gate insulating film 42 disposed between the semiconductor layer 211 and the gate electrode AG.

The semiconductor layer 211 is a part of the semiconductor substrate 21, for example, and includes single crystal silicon. The semiconductor layer 211 is a portion formed by etching a part of an upper surface side of the semiconductor substrate 21. The shape of the semiconductor layer 211 is, for example, a fin (Fin) shape. The fin shape is, for example, a rectangular parallelepiped shape that is long in a gate length direction and short in a gate width direction orthogonal to the gate length direction.

As illustrated in FIG. 3, the gate insulating film 42 is provided so as to continuously cover an upper surface and left and right side surfaces of the semiconductor layer 211. The gate insulating film 42 is constituted by, for example, a silicon oxide film (SiO₂ film). The gate electrode AG is provided so as to continuously cover the upper surface and the left and right side surfaces of the semiconductor layer 211 via the gate insulating film 42. The gate electrode AG is constituted by, for example, a polysilicon (Poly-Si) film.

Thus, the gate electrode AG can simultaneously apply a gate voltage to the upper surface and the left and right side surfaces of the semiconductor layer 211. That is, the gate electrode AG can simultaneously apply the gate voltage to the semiconductor layer 211 from three directions including an upper side and left and right sides. Thus, the gate electrode AG can completely deplete the semiconductor layer 211.

In the present specification, a structure in which a semiconductor layer on an insulating film has a fin shape, and the semiconductor layer is completely depleted by simultaneous application of voltages from three directions including an upper side and left and right sides of the semiconductor layer as in the amplification transistor AMP illustrated in FIG. 3 is referred to as an “FD SOI Fin structure”.

A source region and a drain region of the amplification transistor AMP are provided in a region exposed from below the gate electrode AG in the semiconductor layer 211. In a gate length direction of the amplification transistor AMP, the source region is connected to one side of the semiconductor layer 211 in which a channel is formed, and the drain region is connected to the other side of the semiconductor layer 211 in which a channel is formed. The conductivity type of the source region and the drain region is, for example, N-type.

Although not illustrated, for example, the selection transistor SEL, the reset transistor RST, and the switch transistor FDG have the “FD SOI Fin structure” similarly to the amplification transistor AMP. Note that the FD SOI Fin structure will be described in more detail with reference to a plan view and a cross-sectional view in a fourth embodiment to be described later.

In the second substrate 20, the reset transistor RST, the switch transistor FDG, the amplification transistor AMP, and the selection transistor SEL are separated from each other by the fifth insulating film 45 and covered with the sixth insulating film 46. The fifth insulating film 45 is constituted by, for example, a silicon oxide film (SiO₂ film). The sixth insulating film 46 is constituted by, for example, a SiO₂ film, a silicon nitride film (SiN film), or a film obtained by stacking these films.

A plurality of through holes is provided in the first insulating film 161, the second insulating film 162, the third insulating film 163, the fourth insulating film 164, the fifth insulating film 45, and the sixth insulating film 46. Through wirings 51 and 52 are provided in these through holes. Furthermore, the third wiring layer 53 is provided on the sixth insulating film 46. The gate electrode AG of the amplification transistor AMP is connected to the source of the reset transistor RST and the floating diffusion FD of the first substrate 10 via the through wiring 51 and the third wiring layer 53.

The second wiring layer 18 is constituted by, for example, a polycrystalline silicon film doped with an N-type impurity or a P-type impurity. The second wiring layer 18 is in contact with a side surface of the through wiring 52 and is connected to the well contact region 15 via the through wiring 52. Thus, the potential of the second wiring layer 18 is fixed to the potential of the well region 14 (an example of the “reference potential” of the present disclosure). Note that the reference potential may be a ground potential (GND), a negative constant potential, or a positive constant potential.

Although not illustrated in FIG. 1, for example, a third substrate 30 (see FIG. 1) is disposed on the second substrate 20. Furthermore, in the first substrate 10, a color filter and a light receiving lens are disposed on the opposite side of the surface to which the second substrate 20 is bonded. Note that an example of a cross-sectional structure including the third substrate 30, the color filter, and the light receiving lens will be described in the fifth embodiment described later.

As illustrated in FIGS. 3 and 4, the second wiring layer 18 is disposed between the first wiring layer 17 and at least the channel region (alternatively, the gate electrode AG) of the amplification transistor AMP. Furthermore, as illustrated in FIG. 3, the second wiring layer 18 is in contact with the side surface of the through wiring 52, and is connected to the well contact region 15 via the through wiring 52. Thus, the potential of the second wiring layer 18 is fixed to the reference potential (for example, GND), which is the potential of the well region 14.

Since the second wiring layer 18 fixed to the reference potential is disposed between the first wiring layer 17 and at least the channel region (alternatively, the gate electrode AG) of the amplification transistor AMP, it is possible to suppress the voltage (for example, the voltage applied to the transfer gate TG to turn on and off the transfer transistor TR) applied to the first wiring layer 17 from interfering with the characteristics (for example, threshold voltage Vth) of the amplification transistor AMP. Hereinafter, the interference caused by the voltage is also referred to as bias interference.

### (Manufacturing Method)

Next, a manufacturing method of the imaging device 1 illustrated in FIG. 3 is described. Note that the imaging device 1 is manufactured by using various devices such as a film forming device (including a chemical vapor deposition (CVD) device and a sputtering device), an ion implantation device, a heat treatment device, an etching device, a chemical mechanical polishing (CMP) device, and a bonding device. Hereinafter, these devices are collectively referred to as manufacturing devices.

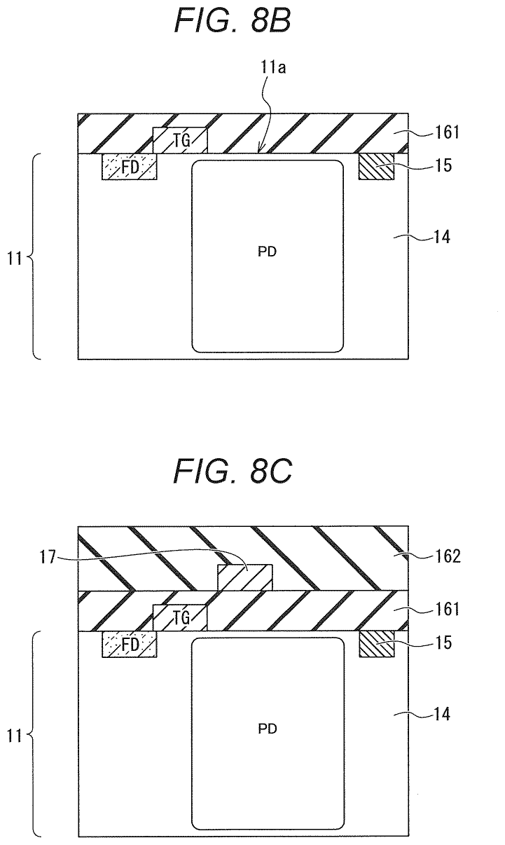

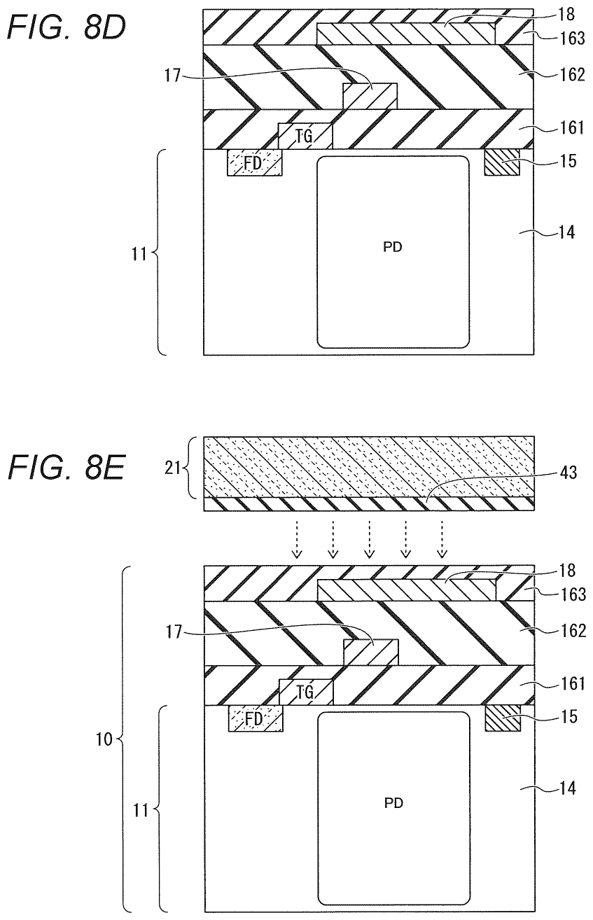

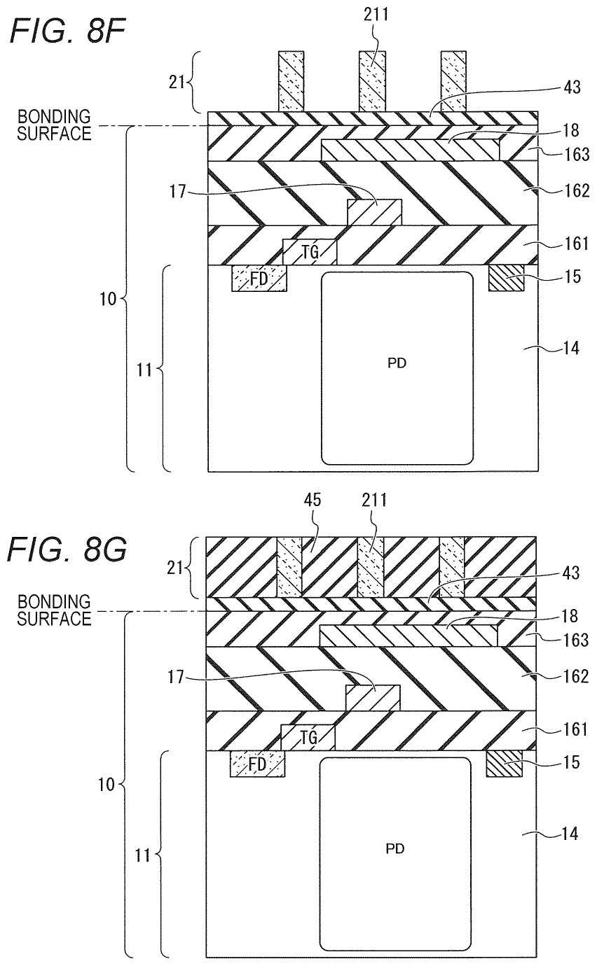

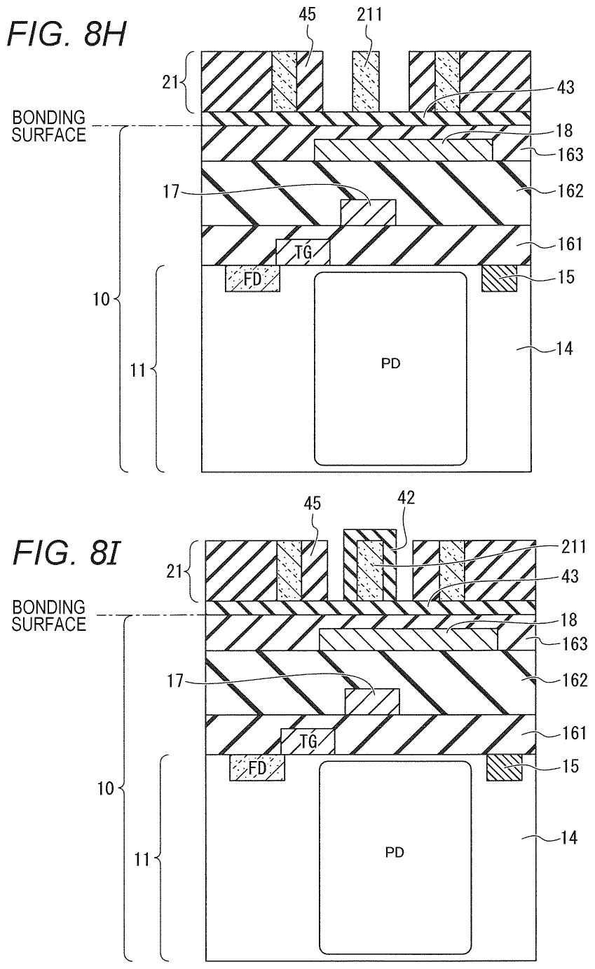

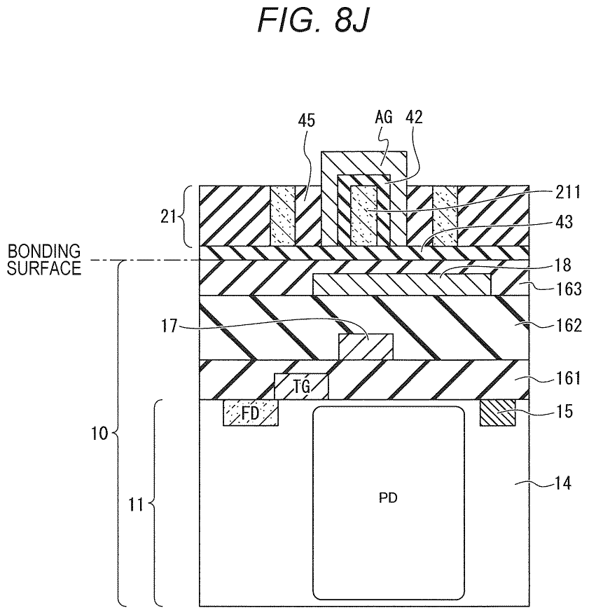

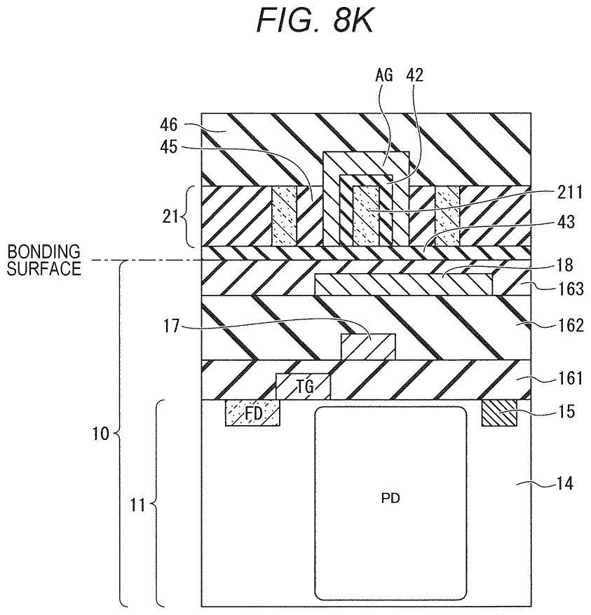

FIGS. 8A to 8K are cross-sectional views illustrating the method for manufacturing the imaging device 1 according to the first embodiment of the present disclosure in order of steps. As illustrated in FIG. 8A, the manufacturing device forms the floating diffusion FD in a desired region of the semiconductor substrate 11 including silicon by using an ion implantation method. Next, the manufacturing device deposits a polycrystalline silicon film using a thermal CVD method, and forms a resist mask having an opening in a desired region by photolithography. Subsequently, the manufacturing device dry-etches the polycrystalline silicon film using a resist mask to form a transfer gate TG which is a gate electrode of the transfer transistor TR (see FIG. 2).

Next, the manufacturing device forms the well contact region 15 in a desired region of the semiconductor substrate 11 using an ion implantation method.

Next, as illustrated in FIG. 8B, the manufacturing device deposits the first insulating film 161 on the front surface 11a of the semiconductor substrate 11 (an example of “one surface of the first semiconductor layer” of the present disclosure) using a plasma CVD method. Thus, the transfer gate TG is covered with the first insulating film 161. Next, the manufacturing device performs CMP processing on the first insulating film 161 to planarize a front surface of the first insulating film 161.

Next, the manufacturing device deposits a polycrystalline silicon film using the thermal CVD method, and forms a resist mask opening in a desired region by photolithography. Next, the manufacturing device dry-etches the polycrystalline silicon film using a resist mask. Thus, as illustrated in FIG. 8C, the first wiring layer 17 electrically connected to the transfer gate TG is formed on the first insulating film 161.

Next, the manufacturing device deposits the second insulating film 162 on the first insulating film 161 using the plasma CVD method. Thus, the first wiring layer 17 is covered with the second insulating film 162. Subsequently, the manufacturing device performs CMP processing on the second insulating film 162 to planarize a front surface of the second insulating film 162.

Next, the manufacturing device deposits a polycrystalline silicon film using the thermal CVD method. Subsequently, the manufacturing device forms, by photolithography, a resist mask that covers a region immediately below the channel of the amplification transistor AMP (see FIG. 3) and opens other regions. Next, the manufacturing device dry-etches the polycrystalline silicon film using a resist mask. Thus, as illustrated in FIG. 8D, the second wiring layer 18 is formed on the second insulating film 162. By fixing the potential of the second wiring layer 18 to the reference potential (for example, GND), the second wiring layer 18 functions as a shield layer for suppressing bias interference from the first wiring layer 17.

Next, the manufacturing device deposits the third insulating film 163 on the second insulating film 162 using the plasma CVD method. Thus, the second wiring layer 18 is covered with the third insulating film 163. Next, the manufacturing device performs CMP processing on the third insulating film 16 to planarize a front surface of the third insulating film 163. Through such steps, the first substrate 10 is completed.

Next, as illustrated in FIG. 8E, the manufacturing device deposits the fourth insulating film 43 on the bonding surface side of the semiconductor substrate 21 with the first substrate 10 using the plasma CVD method. Subsequently, the manufacturing device bonds the third insulating film 163 of the first substrate 10 and the fourth insulating film 43 formed on the semiconductor substrate 21 using a plasma bonding method. A boundary surface between the third insulating film 163 and the fourth insulating film 43 is a bonding surface.

Next, the manufacturing device forms a resist mask on the semiconductor substrate 21 by photolithography, the resist mask opening in a region where the gate electrode of the amplification transistor AMP is to be formed and an element isolation region, and covering the other regions. Subsequently, the manufacturing device dry-etches the semiconductor substrate 21 using a resist mask. Thus, as illustrated in FIG. 8F, the semiconductor layer 211 having a Fin shape to be the channel region of the amplification transistor AMP is formed.

Next, the manufacturing device deposits the fifth insulating film 45 (see FIG. 3) using the plasma CVD method to cover the semiconductor layer 211. Subsequently, as illustrated in FIG. 8G, the manufacturing device performs CMP processing on the fifth insulating film 45 to planarize a front surface of the semiconductor layer 211 and expose the front surface of the semiconductor layer 211. Thus, an element isolation layer including the fifth insulating film 45 is formed around the Fin-shaped semiconductor layer 211.

Next, the manufacturing device forms a resist mask opening in a region where the gate electrode AG (see FIG. 3) of the amplification transistor AMP is to be formed, and covering the other region by photolithography. Subsequently, the manufacturing device dry-etches the fifth insulating film 45 using a resist mask. Thus, as illustrated in FIG. 8H, the left and right side surfaces of the semiconductor layer 211 to be the channel region of the Fin-shaped gate electrode AG are exposed. Thereafter, the resist mask is removed to expose the upper surface of the semiconductor layer 211.

Next, as illustrated in FIG. 8I, the manufacturing device forms the gate insulating film 42 on the upper surface and the left and right side surfaces of the semiconductor layer 211 by a thermal oxidation method. Subsequently, the manufacturing device deposits a polycrystalline silicon film using the thermal CVD method to cover the gate insulating film 42. Next, the manufacturing device forms, by photolithography, a resist mask that covers a region where the gate electrode AG of the amplification transistor AMP is to be formed and opens other regions. Subsequently, the manufacturing device dry-etches the polycrystalline silicon film using a resist mask. Thus, as illustrated in FIG. 8J, the gate electrode AG of the amplification transistor AMP is formed.

Next, as illustrated in FIG. 8K, the manufacturing device deposits the sixth insulating film 46 using the plasma CVD method. Subsequently, the manufacturing device performs CMP processing on a front surface of the sixth insulating film 46 to planarize the front surface. Next, the manufacturing device forms a resist mask on the sixth insulating film 46 by photolithography, the resist mask opening a region where the through wirings 51 and 52 (see FIG. 3) are to be formed, and covering the other regions. Subsequently, the manufacturing device dry-etches the sixth insulating film 46, the fifth insulating film 45, the fourth insulating film 43, the third insulating film 163, the second insulating film 162, and the first insulating film 161 using the resist mask to form a plurality of through holes (for example, a through hole reaching the floating diffusion FD, a through hole reaching the well contact region 15, a through hole reaching the gate electrode AG, and the like).

Next, the manufacturing device fills the through hole with a metal film and deposits the metal film on the sixth insulating film 46 by a sputtering method, a vapor deposition method, a CVD method, or the like. Subsequently, the manufacturing device forms a resist mask on the metal film by photolithography, the resist mask covering a region where the through hole and the third wiring layer 53 (see FIG. 3) are to be formed, and exposing other regions. Then, the manufacturing device dry-etches the metal film using the resist mask. Thus, the through wirings 51 and 52 and the third wiring layer 53 are formed. Through such steps, the imaging device 1 illustrated in FIG. 3 is completed.

### Effect of First Embodiment

As described above, the imaging device 1 according to the first embodiment of the present disclosure includes the semiconductor substrate 11 provided with the sensor pixel 12 that performs photoelectric conversion, the semiconductor substrate 21 disposed on the front surface 11a side of the semiconductor substrate 11 and provided with the pixel transistor (for example, the amplification transistor AMP) for outputting a pixel signal based on charges output from the sensor pixel 12, the insulating layer (for example, an insulating layer having a stacked structure including the first insulating film 161, the second insulating film 162, and the third insulating film 163) disposed between the first semiconductor layer and the semiconductor substrate 21, and the second wiring layer 18 disposed in the insulating layer and between the sensor pixel 12 and the amplification transistor AMP. The potential of the second wiring layer 18 is fixed to the reference potential (for example, GND).

With this configuration, the second wiring layer 18 can electromagnetically block the sensor pixel 12 provided on the semiconductor substrate 11 and the amplification transistor AMP provided on the semiconductor substrate 21, and can suppress electromagnetic interference from the sensor pixel 12 side to the amplification transistor AMP.

For example, the sensor pixel 12 includes a photodiode PD that performs photoelectric conversion, and a transfer transistor TR for transferring a charge generated in the photodiode PD. The second wiring layer 18 is disposed between the photodiode PD provided on the semiconductor substrate 11 and the amplification transistor AMP provided on the semiconductor substrate 21. With this arrangement, the second wiring layer 18 can suppress electromagnetic interference from the photodiode PD to the amplification transistor AMP, and can suppress deterioration of the characteristics (for example, noise characteristics) of the amplification transistor AMP.

Furthermore, the first wiring layer 17 connected to the gate electrode (that is, the transfer gate TG) of the transfer transistor TR is disposed between the photodiode PD and the second wiring layer 18. With this arrangement, the second wiring layer 18 can suppress bias interference from the first wiring layer 17 to the amplification transistor AMP, and can suppress deterioration of characteristics (for example, noise characteristics) of the amplification transistor AMP.

Since bias interference from the semiconductor substrate 11 side to the semiconductor substrate 21 can be suppressed, it is easy to employ the FD SOI Fin structure (which is a structure easily affected by bias interference) for the amplification transistor AMP provided on the semiconductor substrate 21. By employing the FD SOI Fin structure, the effective gate width W of the amplification transistor AMP can be expanded, and the effective area of the amplification transistor AMP can be increased.

Furthermore, the sensor pixel 12 includes the well contact region 15 provided in the semiconductor substrate 11 and the through wiring 52 that is in contact with the well contact region 15 and penetrates the insulating layer of the above-described stacked structure in the thickness direction. The second wiring layer 18 is in contact with the through wiring 52. With this configuration, the second wiring layer 18 can be connected to the well region 14 via the through wiring 52 in contact with the well contact region 15, and the potential of the second wiring layer 18 can be fixed to the potential (reference potential) of the well region 14. Since a dedicated through wiring for connecting the second wiring layer 18 to the reference potential is unnecessary, the arrangement area of the elements in the imaging device 1 can be increased by that amount (alternatively, the chip area of the imaging device 1 can be reduced by that amount). Thus, the layout efficiency of the imaging device 1 can be improved.

### Second Embodiment

In the first embodiment described above, it has been described that the second wiring layer 18 fixed to the reference potential (for example, GND) is disposed between the photodiode PD of the sensor pixel 12 and the amplification transistor AMP. However, the embodiment of the present disclosure is not limited thereto. In the embodiment of the present disclosure, the second wiring layer 18 fixed to the reference potential may be disposed not only between the photodiode PD and the amplification transistor AMP but also between the photodiode PD and another pixel transistor (for example, the selection transistor SEL) other than the amplification transistor AMP.

### (Configuration)

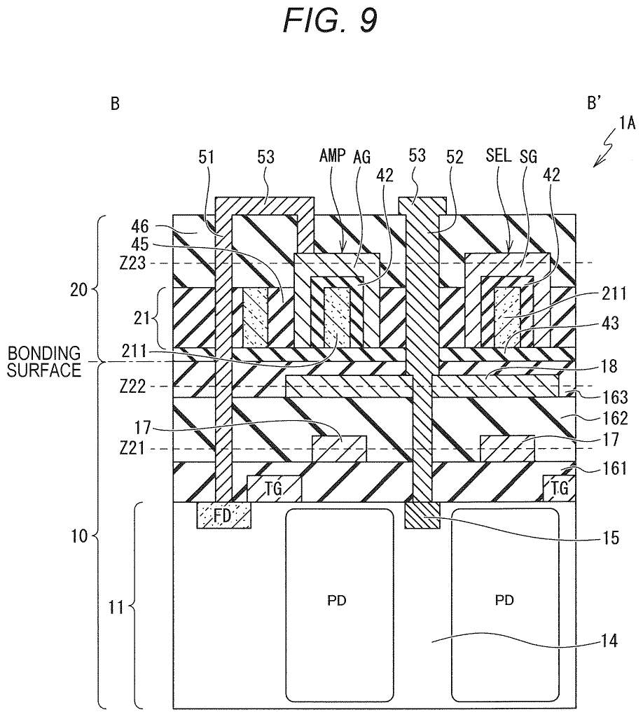

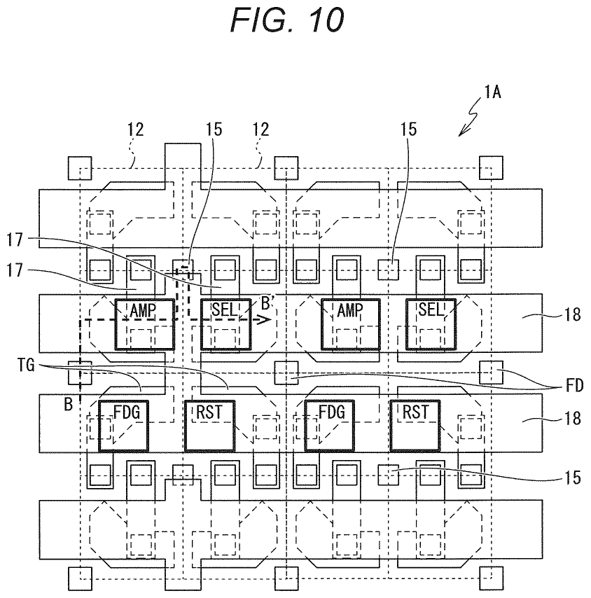

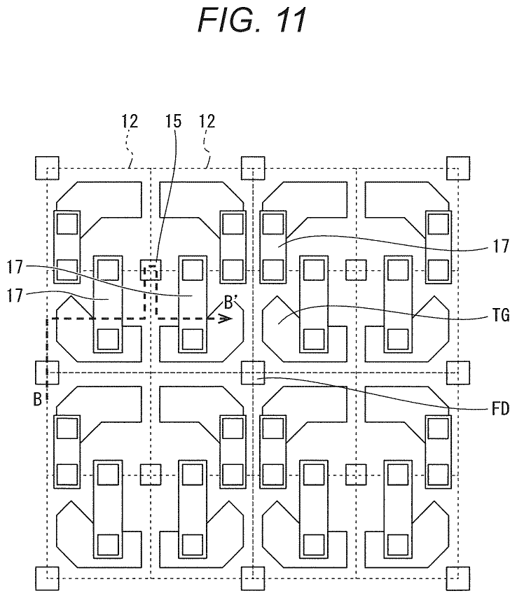

FIG. 9 is a cross-sectional view illustrating a configuration example of an imaging device 1A according to a second embodiment of the present disclosure. FIG. 10 is a plan view illustrating a configuration example of an imaging device 1A according to the second embodiment of the present disclosure. FIG. 10 illustrates a cross section obtained by cutting the plan view illustrated in FIG. 9 along line B-B′, and illustrates a cross section of a stack including the first substrate 10 and the second substrate 20. FIGS. 11 to 13 are cross-sectional views of the imaging device 1A illustrated in FIG. 9 taken along a horizontal plane orthogonal to the thickness direction thereof. More specifically, FIG. 5 illustrates a cross section taken along a horizontal plane Z21 passing through the first wiring layer 17. FIG. 6 illustrates a cross section taken along a horizontal plane Z22 passing through the second wiring layer 18. FIG. 7 illustrates a cross section taken along a horizontal plane Z23 passing through the gate electrode AG of the amplification transistor AMP and a gate electrode SG of the selection transistor SEL.

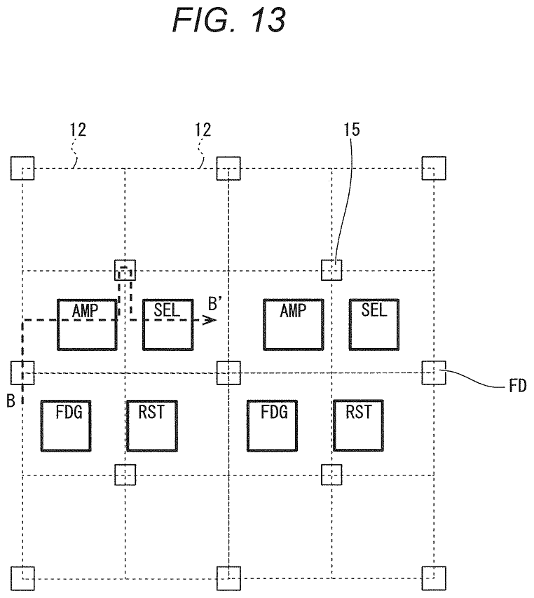

Note that a view in which the cross-sectional views of FIGS. 11 to 13 are aligned and superimposed corresponds to FIG. 10. Furthermore, in FIGS. 10 to 13, illustration of the first insulating film 161, the second insulating film 162, the third insulating film 163, the fourth insulating film 164, the fifth insulating film 45, the sixth insulating film 46, the through wirings 51 and 52, and the third wiring layer 53 illustrated in FIG. 9 is omitted. Furthermore, in FIGS. 10 and 13, the reset transistor RST, the switch transistor FDG, the amplification transistor AMP, and the selection transistor SEL are schematically illustrated by rectangles.

As illustrated in FIGS. 9 and 10, in the imaging device 1A according to the second embodiment, the second wiring layer 18 fixed to the reference potential (for example, GND) is disposed between the photodiode PD and the amplification transistor AMP and between the photodiode PD and the selection transistor SEL. For example, similarly to the amplification transistor AMP, the selection transistor SEL has the “FD SOI Fin structure”, and its channel is formed in the semiconductor layer 211. In the imaging device 1A, the second wiring layer 18 fixed to the reference potential is disposed between the photodiode PD and the channel region of the amplification transistor AMP and between the photodiode PD and the channel region of the selection transistor SEL.

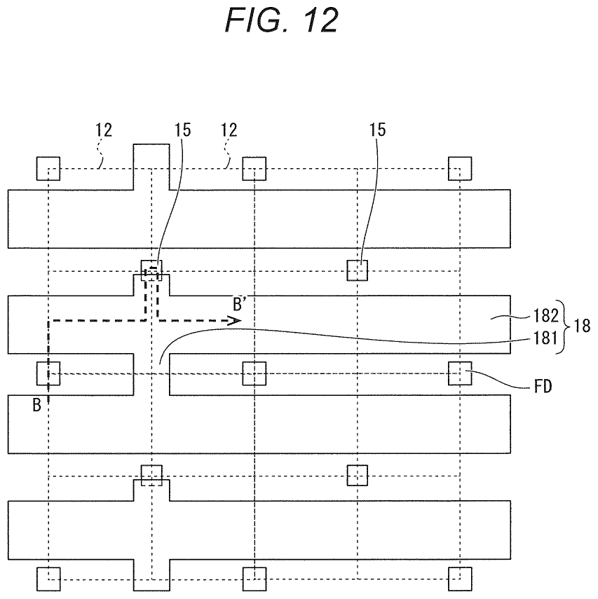

As illustrated in FIGS. 10 and 12, in the imaging device 1A, the second wiring layer 18 is continuously provided from one sensor pixel 12 to another sensor pixel 12 among the plurality of sensor pixels 12. The shape of the second wiring layer 18 in plan view is, for example, a grid frame shape. That is, the second wiring layer 18 includes first straight line portions 181 extending in the X-axis direction in plan view and second straight line portions 182 extending in the Y-axis direction in plan view, and has a shape in which the first straight line portions 181 and the second straight line portions 182 are connected to each other. The first straight line portions 181 are arranged at regular intervals in the Y-axis direction, and are arranged so as to overlap with respective each channel region of the pixel transistors (the amplification transistor AMP, the selection transistor SEL, the reset transistor RST, and the switch transistor FDG). The second straight line portions 182 are arranged so as to connect one first straight line portion 181 and another first straight line portion 181 adjacent to each other in the Y-axis direction.

The second wiring layer 18 is in contact with the through wiring 52. For example, a side surface of the second wiring layer 18 is in contact with the through wiring 52. Thus, the second wiring layer 18 is connected to the well contact region 15 via the through wiring 52. The potential of the second wiring layer 18 is fixed to a reference potential (for example, GND) which is the potential of the well region 14.

### Effects of Second Embodiment

The imaging device 1A according to the second embodiment of the present disclosure has effects similar to those of the imaging device 1 according to the first embodiment.

Furthermore, in the imaging device 1A, the second wiring layer 18 fixed to the reference potential is arranged not only between the sensor pixel 12 and the amplification transistor AMP but also between the sensor pixel 12 and the selection transistor SEL. Thus, the second wiring layer 18 can electromagnetically block between the sensor pixel 12 and the selection transistor SEL, and can suppress electromagnetic interference with the selection transistor SEL from the sensor pixel 12 side. For example, the second wiring layer 18 can suppress bias interference from the first wiring layer 17 to the selection transistor SEL. Thus, it is possible to suppress deterioration of the characteristics (for example, switching characteristics) of the selection transistor SEL.

### Modification of Second Embodiment

In the second embodiment described above, it has been described that the shape of the second wiring layer 18 in plan view is a grid frame shape. However, in the second embodiment of the present disclosure, the shape of the second wiring layer 18 is not limited to the grid frame shape, and may be another shape.

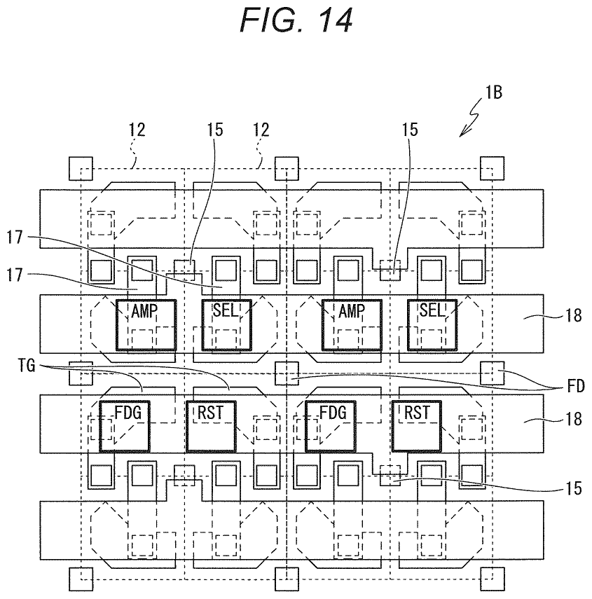

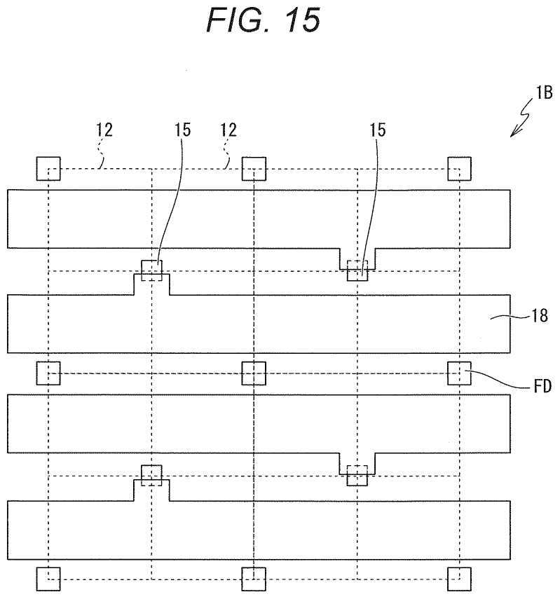

FIG. 14 is a plan view illustrating an imaging device 1B according to a modification of the second embodiment of the present disclosure. FIG. 15 is a plan view illustrating a second wiring layer 18 of the imaging device 1B according to a modification of the second embodiment of the present disclosure. As illustrated in FIGS. 14 and 15, the shape of the second wiring layer 18 in plan view may be a linear shape extending in one direction (for example, in the X-axis direction). That is, the second wiring layer 18 may include only the first straight line portions 181 extending in one direction (for example, in the X-axis direction) in plan view.

Also in this modification, the first straight line portions 181 are arranged at regular intervals in the Y-axis direction, and are arranged so as to overlap with the channel regions of the pixel transistors. Each of the first straight line portions 181 is in contact with the through wiring 52. The first straight line portion 181 is connected to the well contact region 15 via the through wiring 52. The potential of the first straight line portion 181 is fixed to a reference potential which is the potential of the well region 14.

Even with such a configuration, the imaging device 1B has effects similar to those of the imaging device 1A according to the second embodiment.

### Third Embodiment

In the first embodiment described above, it has been described that each of the amplification transistor AMP, the selection transistor SEL, the reset transistor RST, and the switch transistor FDG has the “FD SOI Fin structure”. Furthermore, in the second embodiment, an aspect in which each of the amplification transistor AMP and the selection transistor SEL has the “FD SOI Fin structure” is illustrated (see FIG. 9). However, the embodiment of the present disclosure is not limited thereto. In the embodiment of the present disclosure, at least a part of the pixel transistors (the amplification transistor AMP, the selection transistor SEL, the reset transistor RST, and the switch transistor FDG) may have a bulk structure instead of the “FD SOI Fin structure”.

### (Configuration)

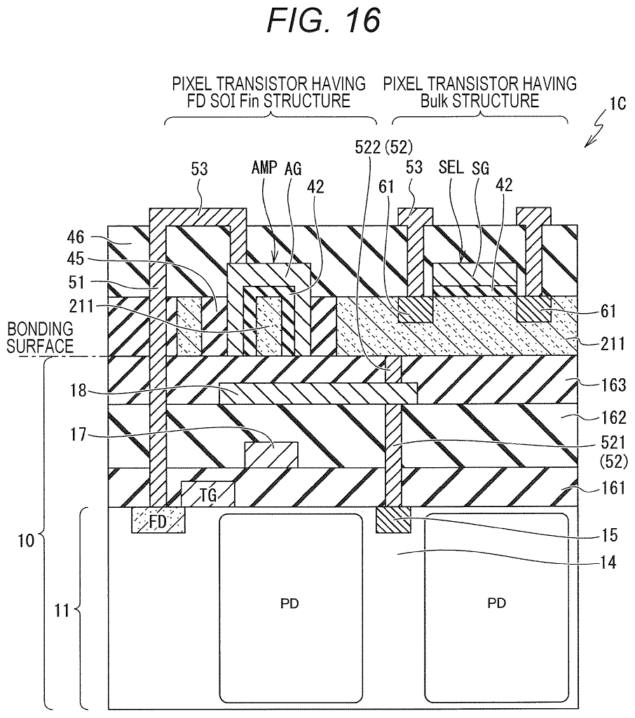

FIG. 16 is a cross-sectional view illustrating a configuration example of an imaging device 1C according to a third embodiment of the present disclosure. As illustrated in FIG. 16, in the imaging device 1C according to the third embodiment, in the selection transistor SEL, the semiconductor layer 211 in which the channel is formed has a bulk structure instead of the Fin structure. In the bulk structure, the gate voltage is applied only from the upper side of the semiconductor layer 211. When the gate voltage becomes a value equal to or larger than a threshold value, an on-current flows from one of the source/drain regions 61 to the other, but since the gate voltage is applied only from one direction on the upper side, the channel region of the selection transistor SEL is not completely depleted. The selection transistor SEL having the bulk structure is, for example, a partially depleted type.

As illustrated in FIG. 16, also in the imaging device 1C, the second wiring layer 18 is arranged between the photodiode PD and the channel region of the amplification transistor AMP. Furthermore, the first wiring layer 17 is disposed between the photodiode PD and the second wiring layer 18. Thus, it is a structure in which the second wiring layer 18 is disposed between the first wiring layer 17 and the channel region of the amplification transistor AMP.

Also in the imaging device 1C, the second wiring layer 18 is in contact with the through wiring 52 and is connected to the well contact region 15 via the through wiring 52. Thus, the potential of the second wiring layer 18 is fixed to the reference potential (for example, GND).

Furthermore, in the imaging device 1C, the through wiring 52 includes a first portion 521 and a second portion 522. The first portion 521 connects the well contact region 15 and the second wiring layer 18. The second portion 522 connects the second wiring layer 18 and the semiconductor layer 211 (hereinafter also referred to as a bulk semiconductor layer 211) in which the selection transistor SEL having a bulk structure is provided. For example, an upper end of the second portion 522 is in contact with a lower surface of the bulk semiconductor layer 211. Thus, not only the potential of the second wiring layer 18 but also the potential of the bulk semiconductor layer 211 is fixed to the reference potential (for example, GND).

### (Manufacturing Method)

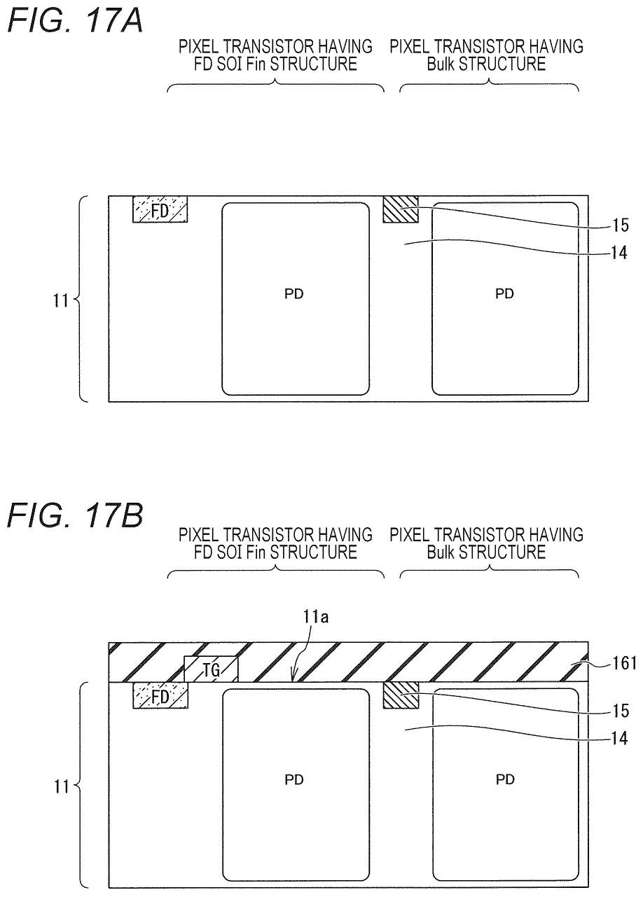

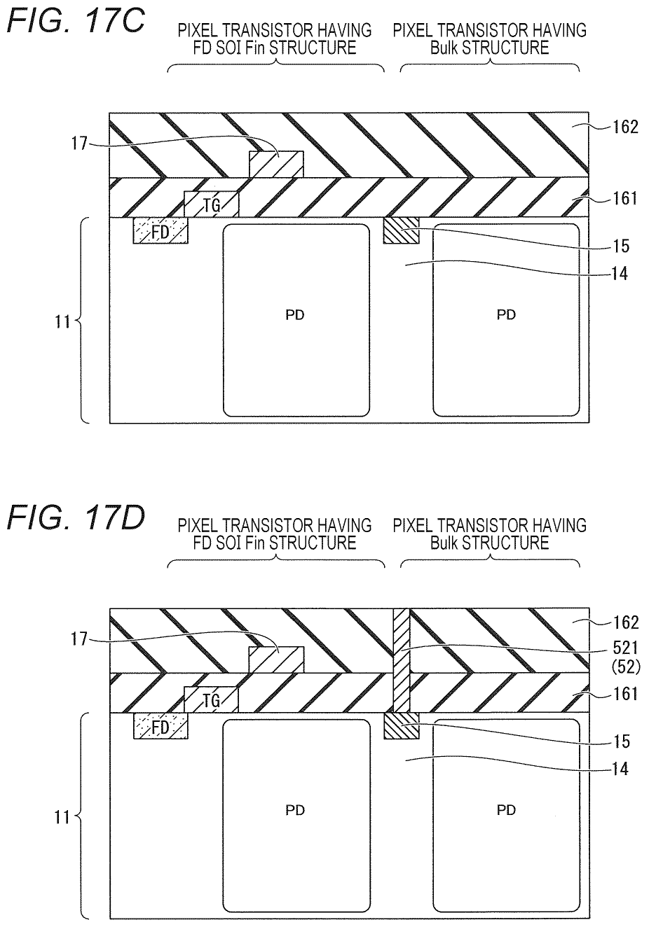

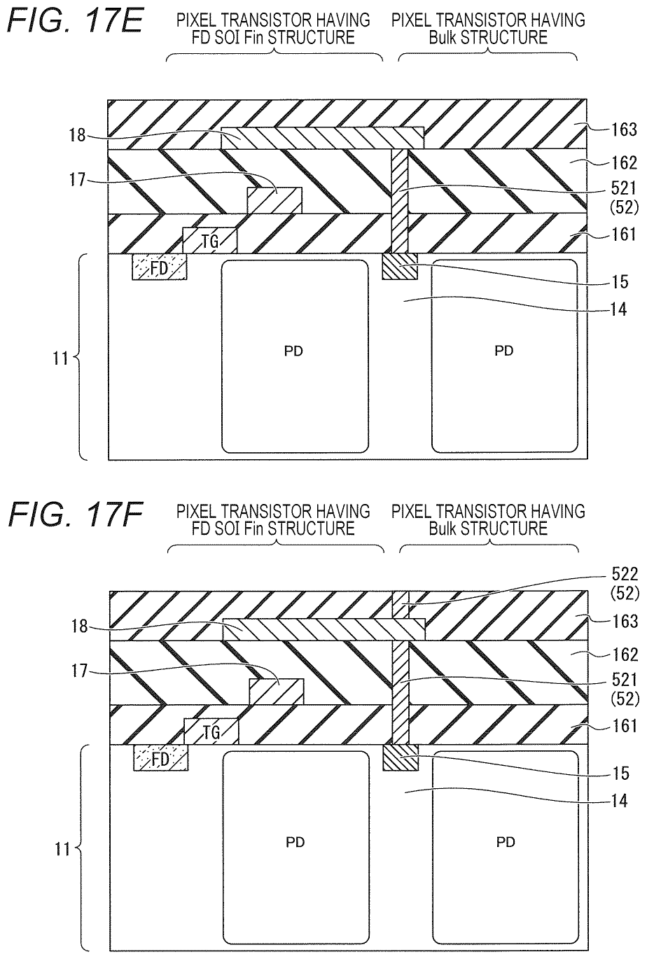

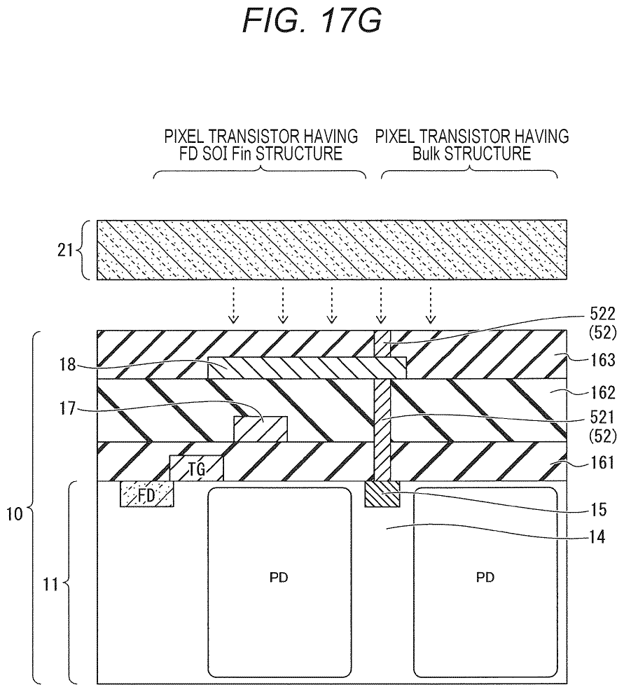

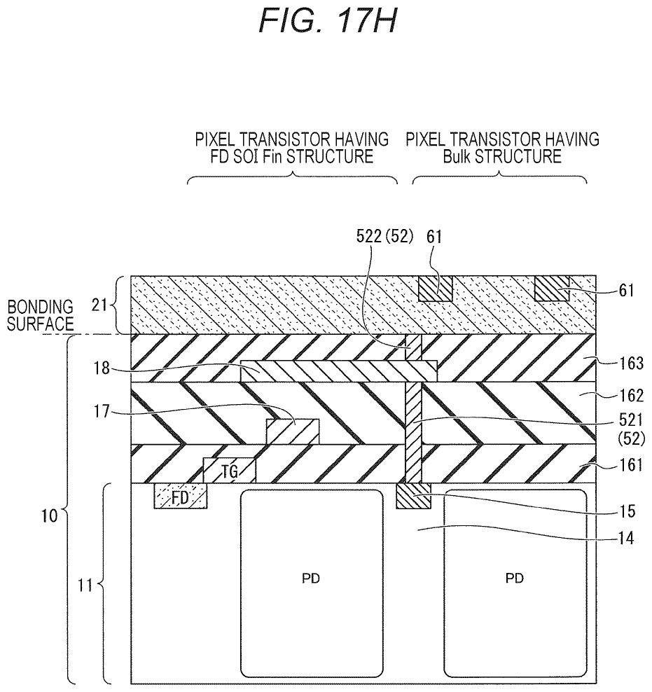

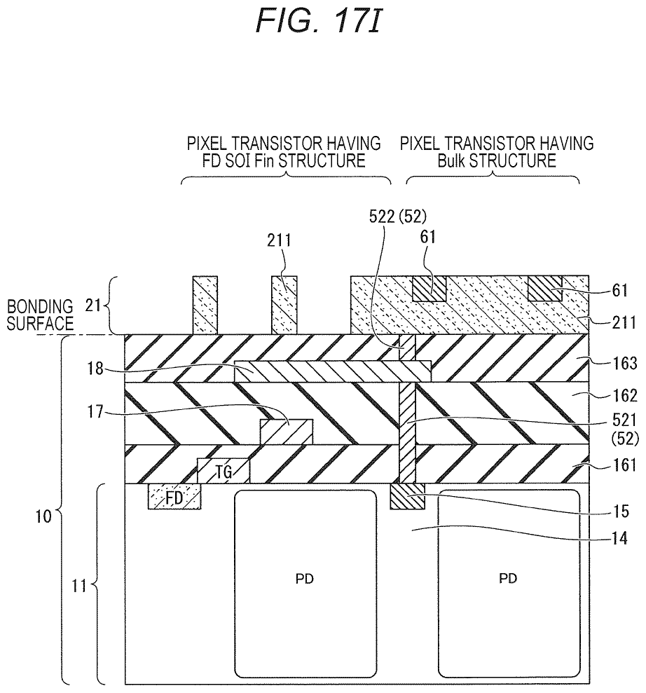

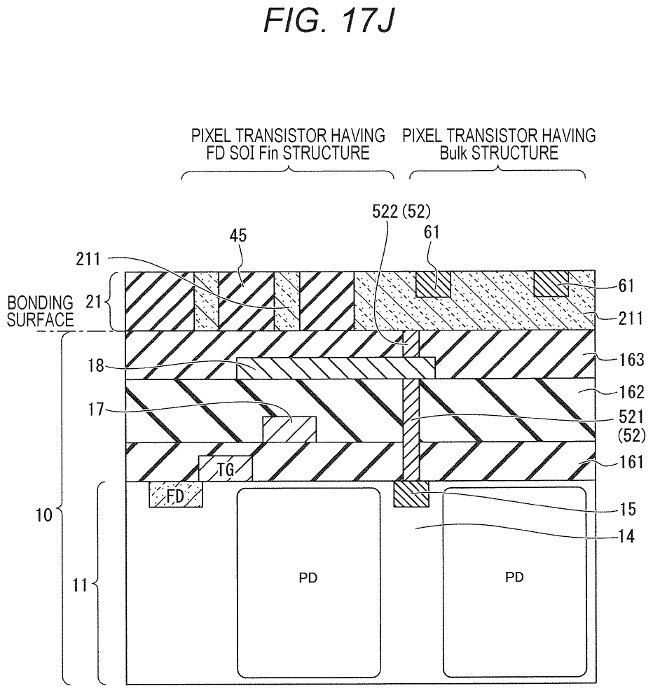

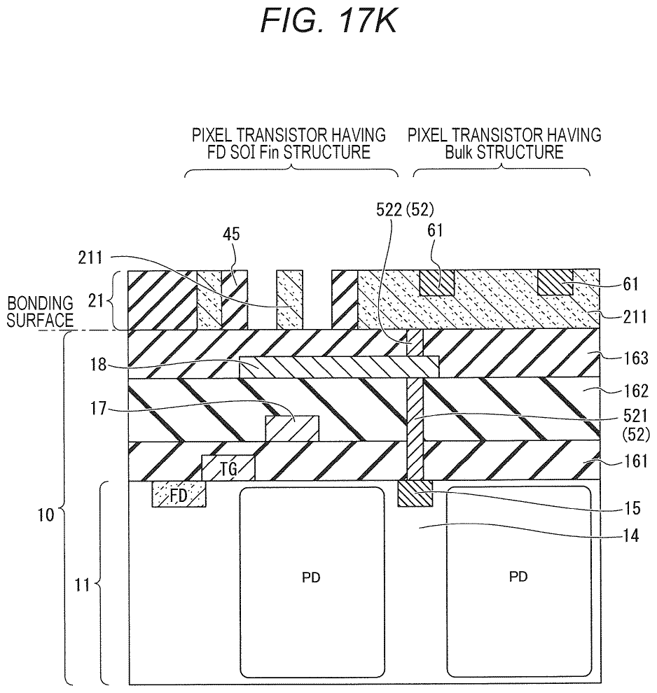

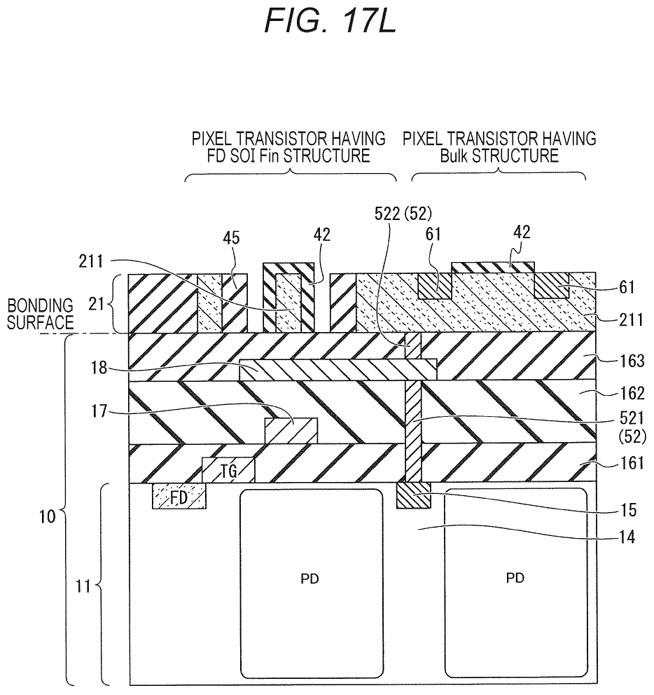

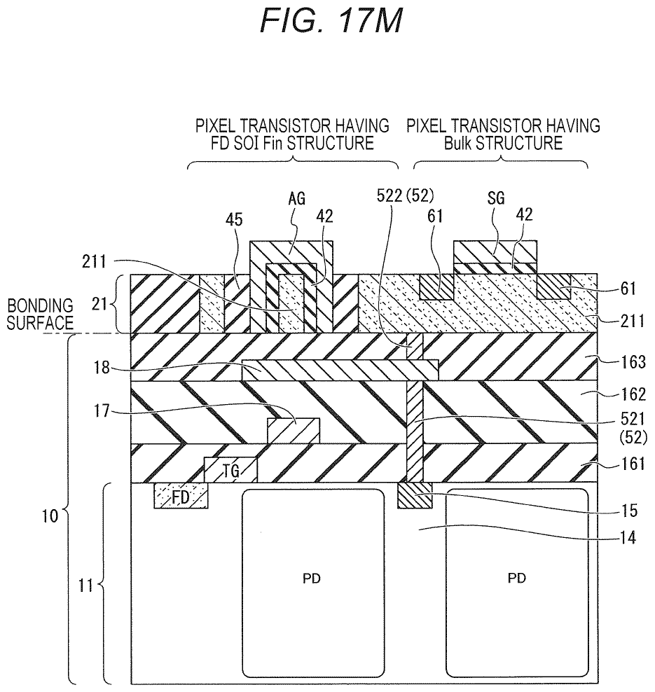

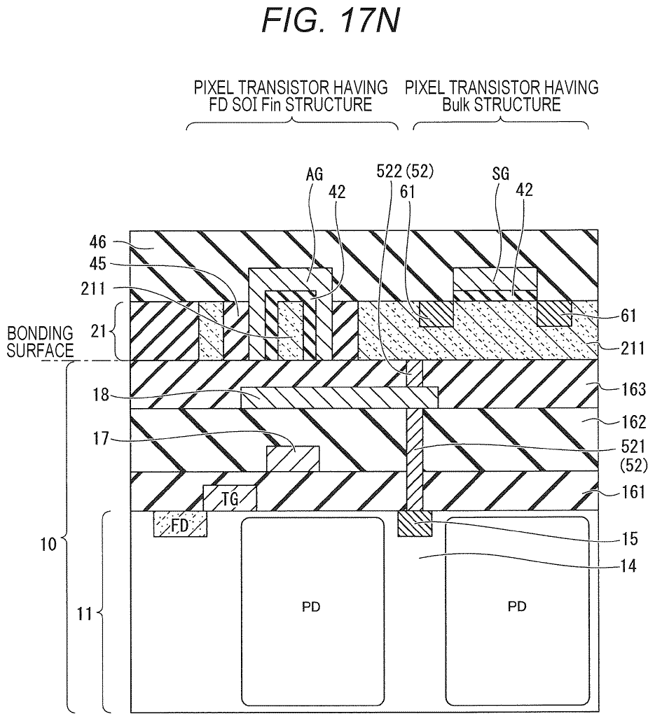

FIGS. 17A to 17N are cross-sectional views illustrating the method of manufacturing the imaging device 1C according to the third embodiment of the present disclosure in order of steps. As illustrated in FIG. 17A, the manufacturing device forms the floating diffusion FD on the semiconductor substrate 11 using the ion implantation method. Next, the manufacturing device deposits a polycrystalline silicon film using the thermal CVD method. Subsequently, the manufacturing device patterns the polycrystalline silicon film by photolithography and dry etching to form the transfer gate TG.

Next, the manufacturing device forms the well contact region 15 on the semiconductor substrate 11 using an ion implantation method.

Next, as illustrated in FIG. 17B, the manufacturing device deposits the first insulating film 161 on the front surface 11a of the semiconductor substrate 11 using the plasma CVD method to cover the transfer gate TG. Next, the manufacturing device performs CMP processing on the first insulating film 161 to planarize the front surface of the first insulating film 161.

Next, the manufacturing device deposits a polycrystalline silicon film using the thermal CVD method. Subsequently, the manufacturing device patterns the polycrystalline silicon film by photolithography and dry etching to form the first wiring layer 17 as illustrated in FIG. 17C.

Next, the manufacturing device deposits the second insulating film 162 on the first insulating film 161 using the plasma CVD method to cover the first wiring layer 17. Subsequently, the manufacturing device performs CMP processing on the second insulating film 162 to planarize the front surface of the second insulating film 162.

Next, the manufacturing device forms a through hole having the well contact region 15 as a bottom surface in the second insulating film 162 and the first insulating film 161 by photolithography and dry etching. Subsequently, the manufacturing device fills the through hole with a metal film and deposits the metal film on the second insulating film 162 by a sputtering method, a vapor deposition method, a CVD method, or the like. Next, the manufacturing device removes the metal film from the region other than the through hole by photolithography and dry etching. Thus, as illustrated in FIG. 17D, the first portion 521 of the through wiring 52 is formed.

Next, the manufacturing device deposits a polycrystalline silicon film on the second insulating film 162 using the thermal CVD method. The polycrystalline silicon film is formed so as to be in contact with an upper end of the first portion 521 of the through wiring 52.

Next, the polycrystalline silicon film is patterned by photolithography and dry etching. Thus, as illustrated in FIG. 17E, the second wiring layer 18 in contact with the first portion 521 of the through wiring 52 is formed.

Next, the manufacturing device deposits the third insulating film 163 on the second insulating film 162 using the plasma CVD method to cover the second wiring layer 18.

Next, the manufacturing device forms a through hole having the second wiring layer 18 as a bottom surface in the third insulating film 163 by photolithography and dry etching. Subsequently, the manufacturing device fills the through hole with a metal film and deposits the metal film on the third insulating film 163 by a sputtering method, a vapor deposition method, a CVD method, or the like. Next, the manufacturing device removes the metal film from the region other than the through hole by photolithography and dry etching. Thus, as illustrated in FIG. 17F, the second portion 522 of the through wiring 52 is formed. Through such steps, the first substrate 10 is completed.

Next, as illustrated in FIG. 17G, the manufacturing device bonds the third insulating film 163 of the first substrate 10 and the semiconductor substrate 21 using a plasma bonding method. A boundary surface between the third insulating film 163 and the semiconductor substrate 21 is a bonding surface.

Next, as illustrated in FIG. 17H, the manufacturing device introduces a P-type impurity and an N-type impurity into a region where a pixel transistor (for example, the selection transistor SEL) having a bulk structure is to be formed in the semiconductor substrate 21 by an ion implantation method to form a P-type well region (not illustrated) and an N-type source/drain region 61.

Next, the manufacturing device patterns a region where the pixel transistor (for example, the amplification transistor AMP) having the FD SOI Fin structure is formed in the semiconductor substrate 21 by photolithography and dry etching. Thus, as illustrated in FIG. 17I, the semiconductor layer 211 having the Fin shape to be the channel region of the amplification transistor AMP is formed.

Next, the manufacturing device deposits the fifth insulating film 45 (see FIG. 3) using the plasma CVD method to cover the semiconductor layer 211. Subsequently, the manufacturing device performs CMP processing on the fifth insulating film 45 to planarize the front surface of the semiconductor layer 211 and expose the front surface of the semiconductor layer 211. Thus, as illustrated in FIG. 17J, an element isolation layer including the fifth insulating film 45 is formed around the Fin-shaped semiconductor layer 211.

Next, the manufacturing device patterns the fifth insulating film 45 by photolithography and dry etching to expose the left and right side surfaces of the Fin-shaped semiconductor layer 211 as illustrated in FIG. 17K.

Next, as illustrated in FIG. 17L, the manufacturing device forms the gate insulating film 42 using a thermal oxidation method. In the region where the pixel transistor (for example, the amplification transistor AMP) of the FD SOI Fin structure is formed, the gate insulating film 42 is formed on the upper surface and the left and right side surfaces of the second semiconductor layer of the Fin shape. In the region where the pixel transistor (for example, the selection transistor SEL) having the bulk structure is formed, the gate insulating film 42 is formed on the upper surface of the bulk semiconductor layer 211.

Subsequently, the manufacturing device deposits a polycrystalline silicon film using the thermal CVD method to cover the gate insulating film 42. Next, the manufacturing device patterns the polycrystalline silicon film by photolithography and dry etching to form the gate electrode AG of the amplification transistor AMP and the gate electrode SG of the selection transistor SEL as illustrated in FIG. 17M.

Next, as illustrated in FIG. 17N, the manufacturing device deposits the sixth insulating film 46 using the plasma CVD method. Subsequently, the manufacturing device forms a plurality of through holes (for example, a through hole reaching the floating diffusion FD, a through hole reaching the gate electrode AG, a through hole reaching the gate electrode SG, a through hole reaching the source/drain region 61, and the like) in the sixth insulating film 46 by photolithography and dry etching.

Next, the manufacturing device fills the through hole with a metal film and deposits the metal film on the sixth insulating film 46 by a sputtering method, a vapor deposition method, a CVD method, or the like. Subsequently, the manufacturing device patterns the metal film by photolithography and dry etching. Thus, the through wirings 51 and 52 and the third wiring layer 53 are formed. Through such steps, the imaging device 1C illustrated in FIG. 16 is completed.

### Effect of Third Embodiment

The imaging device 1C according to the third embodiment of the present disclosure has effects similar to those of the imaging device 1 according to the first embodiment.

### Fourth Embodiment

Next, as a fourth embodiment of the present disclosure, a configuration example of the pixel transistor (for example, the amplification transistor AMP) having the FD SOI Fin structure will be described in more detail with reference to a plan view and a cross-sectional view. Note that, in the following description, the direction is sometimes described using terms such as an X-axis direction, a Y-axis direction, and a Z-axis direction. For example, the X-axis direction and the Y-axis direction are directions parallel to a front surface 211a of the semiconductor layer 211. The X-axis direction and the Y-axis direction are also referred to as horizontal directions. The Z-axis direction is a direction perpendicular to the semiconductor layer 211. The Z-axis direction is a thickness direction of the semiconductor layer 211, and is also a depth direction of trenches H1 and H2. The X-axis direction, the Y-axis direction, and the Z-axis direction are orthogonal to each other.

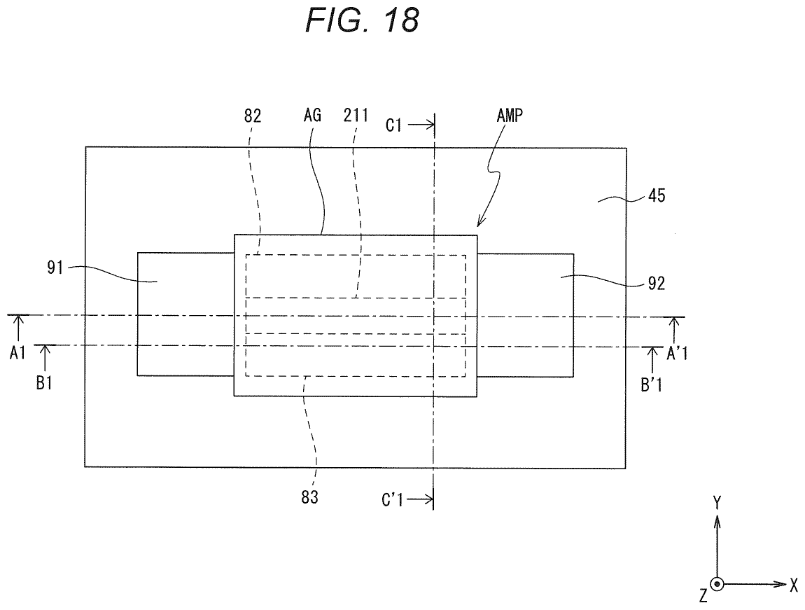

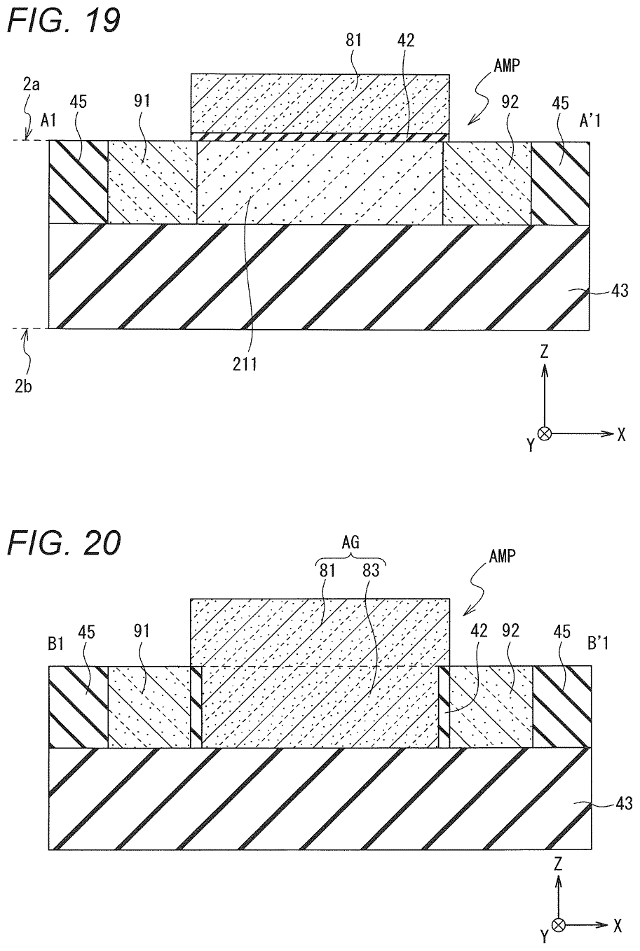

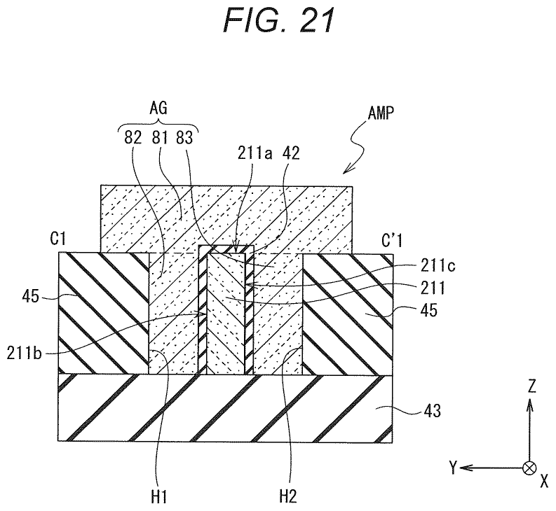

FIG. 18 is a plan view illustrating a configuration example of a pixel transistor (for example, the amplification transistor AMP) having the FD SOI Fin structure according to the fourth embodiment of the present disclosure. FIGS. 19 to 21 are cross-sectional views illustrating configuration examples of the pixel transistor (for example, the amplification transistor AMP) having the FD SOI Fin structure according to the fourth embodiment of the present disclosure. FIG. 19 illustrates a cross section obtained by cutting the plan view illustrated in FIG. 18 along line A1-A′1. FIG. 20 illustrates a cross section obtained by cutting the plan view illustrated in FIG. 18 along line B1-B′1. FIG. 21 illustrates a cross section obtained by cutting the plan view illustrated in FIG. 18 along line C1-C′1.

As illustrated in FIGS. 18 to 21, the amplification transistor AMP having the FD SOI Fin structure is provided on the fourth insulating film 43 (an example of a “bottom insulating film” of the present disclosure), and the periphery thereof is surrounded by the fifth insulating film which is the element isolation layer.

As described above, the semiconductor layer 211 serving as the channel region of the FD SOI Fin structure is a fin-shaped portion formed by etching a part of the upper surface side of the semiconductor substrate 21 (see FIG. 3). The fin shape is, for example, a rectangular parallelepiped shape that is long in the gate length direction (in FIG. 18, the X-axis direction) and short in the gate width direction (in FIG. 18, the Y-axis direction and the Z-axis direction) orthogonal to the gate length direction. The semiconductor layer 211 has an upper surface 211a, a first side surface 211b, and a second side surface 211c. The first side surface 211b is located on one side of the upper surface 211a in the Y-axis direction. The second side surface 211c is located on another side of the upper surface 211a in the Y-axis direction. The conductivity type of the semiconductor layer 211 is not particularly limited, but for example, in a case where the amplification transistor AMP is an NMOS, the conductivity type of the semiconductor layer 211 is a P-type.

The amplification transistor AMP includes the P-type semiconductor layer 211 in which a channel is formed, the gate insulating film 42, the gate electrode AG, and a source region 91 and a drain region 92 provided in the semiconductor substrate 21.

As illustrated in FIG. 21, in the Y-axis direction, a trench H1 with the fourth insulating film 43 as a bottom surface is provided on one side of the semiconductor layer 211, and a trench H2 with the fourth insulating film 43 as a bottom surface is provided on the another side of the semiconductor layer 211. A second portion 82 of the gate electrode AG is disposed in the trench H1. A third portion 83 of the gate electrode AG is disposed in the trench H2. The second portion 82 and the third portion 83 will be described later. The semiconductor layer 211 is sandwiched from the Y-axis direction by the second portion 82 disposed in the trench H1 and the third portion 83 disposed in the trench H2.

The gate insulating film 42 is provided so as to cover the upper surface 211a, the first side surface 211b, and the second side surface 211c of the semiconductor layer 211. The first side surface 211b is located on the one side of the upper surface 211a in the Y-axis direction. The second side surface 211c is located on the another side of the upper surface 211a in the Y-axis direction. The gate insulating film 42 is constituted by, for example, a silicon oxide film (SiO₂ film).

The gate electrode AG covers the semiconductor layer 211 via the gate insulating film 42. For example, the gate electrode AG includes a first portion 81 facing the upper surface 211a of the semiconductor layer 211 via the gate insulating film 42, a second portion 82 facing the first side surface 211b of the semiconductor layer 211 via the gate insulating film 42, and a third portion 83 facing the second side surface 211c of the semiconductor layer 211 via the gate insulating film 42. The second portion 82 and the third portion 83 are connected to a lower surface of the first portion 81.

Therefore, the gate electrode AG can simultaneously apply the gate voltage to the upper surface 211a, the first side surface 211b, and the second side surface 211c of the semiconductor layer 211. That is, the gate electrode AG can simultaneously apply the gate voltage to the semiconductor layer 211 from three directions including an upper side and left and right sides. Thus, the gate electrode AG can completely deplete the semiconductor layer 211. The gate electrode AG is constituted by, for example, a polysilicon (Poly-Si) film.

The source region 91 and the drain region 92 are provided in the semiconductor substrate 21 (see FIG. 3). As illustrated in FIGS. 18 to 20, in the X-axis direction, the source region 91 is connected to one side of the semiconductor layer 211, and the drain region 92 is connected to another side of the semiconductor layer 211. The source region 91 and the drain region 92 are of a first conductivity type (for example, N-type).

A MOS transistor having the FD SOI Fin structure may be referred to as a MOS transistor having a digging gate structure from a shape in which the second portion 82 and the third portion 83 of the gate electrode AG are arranged in the trenches H1 and H2. Alternatively, since the semiconductor layer 211 has a fin shape, it may be referred to as a fin field effect transistor (FinFET). Alternatively, the two shapes described above may be referred to as a dug FinFET.

Furthermore, since the second portion 82 and the third portion 83 of the gate electrode AG are embedded in the trenches H1 and H2, they may be referred to as gate digging portions. In the MOS transistor having the FD SOI Fin structure, front surfaces of the gate digging portions (for example, the second portion 82 and the third portion 83) form substantially the same plane as a front surface of the semiconductor layer (for example, the semiconductor layer 211) and is in contact with the insulating film (for example, the gate insulating film 42 and the fifth insulating film 45) in a certain cross section (for example, a cross section taken along an X-Y plane). Furthermore, the gate digging portion and the lower surface of the semiconductor layer 211 are also in contact with the fourth insulating film 43.

### Fifth Embodiment

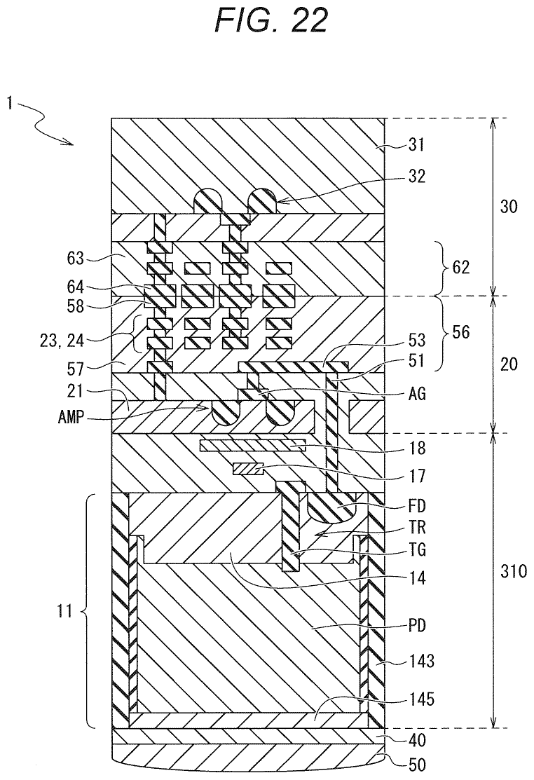

Next, as a fifth embodiment of the present disclosure, an example of a cross-sectional configuration of an imaging device 1 including three substrates illustrated in FIG. 1, a color filter, and a light receiving lens will be described. FIG. 22 is a diagram illustrating a cross-sectional configuration example of the imaging device 1 according to the fifth embodiment of the present disclosure. As illustrated in FIG. 22, the imaging device 1 includes the first substrate 10, the second substrate 20 bonded to a front surface (in FIG. 22, an upper surface) side of the first substrate 10, and the third substrate 30 bonded to a front surface (in FIG. 22, an upper surface) side of the second substrate 20.

The first substrate 10 is provided with a plurality of photodiodes PD. The photodiode PD is provided for each sensor pixel 12 (see FIG. 1). One adjacent photodiode PD and the other adjacent photodiode PD are separated from each other by an element isolation layer 143. The element isolation layer 143 is formed by shallow trench isolation (STI), for example.

On a back surface (in FIG. 22, a lower surface) side of the first substrate 10, a fixed charge film 145 in contact with the back surface is provided. The fixed charge film 145 is negatively charged in order to suppress generation of a dark current due to an interface state on the light-receiving side of the first substrate 10. The fixed charge film 145 is constituted by, for example, an insulating film having a negative fixed charge. Examples of the material of such an insulating film include hafnium oxide, zircon oxide, aluminum oxide, titanium oxide, and tantalum oxide. A hole accumulation layer is formed at the interface on the light-receiving side of the semiconductor substrate 11 by the electric field induced by the fixed charge film 145. The hole accumulation layer suppresses generation of electrons from the interface.

A color filter 40 and a light receiving lens 50 are provided on the back surface (FIG. 22 illustrates a lower surface, that is, a light incident surface) side of the first substrate 10. The color filter 40 is provided in contact with the fixed charge film 145, and is provided at a position facing the photodiode PD via the fixed charge film 145. The light receiving lens 50 is provided in contact with the color filter 40, and is provided at a position facing the photodiode PD via the color filter 40 and the fixed charge film 145.

The second substrate 20 includes a wiring layer 56, an interlayer insulating film 57 that separates layers (that is, between upper and lower wirings) of the wiring layer 56, and a pad electrodes 58 connected to the wiring layer 56 and exposed on the front surface of the interlayer insulating film 57. The wiring layer 56 and the pad electrodes 58 are formed by, for example, copper (Cu). The interlayer insulating film 57 is constituted by, for example, a SiO₂ film.

The third substrate 30 includes the semiconductor substrate 31, the logic circuit 32 provided on a front surface (in FIG. 22, a lower surface) side of the semiconductor substrate 31, a wiring layer 62 provided on the front surface side of the semiconductor substrate 31, an interlayer insulating film 63 that separates layers (that is, between upper and lower wirings) of the wiring layer 62, and pad electrodes 64 connected to the wiring layer 62 and exposed on a front surface of the interlayer insulating film 63. As illustrated in FIG. 1, the logic circuit 32 includes, for example, the vertical drive circuit 33, the column signal processing circuit 34, the horizontal drive circuit 35, and the system control circuit 36. The wiring layer 62 and the pad electrodes 64 are formed by Cu, for example. The interlayer insulating film 63 is constituted by, for example, a SiO₂ film.

The second substrate 20 and the third substrate 30 are electrically connected to each other by bonding the pad electrodes 58 and 64 to each other. The third substrate 30 is bonded to the second substrate 20 with the front surface of the semiconductor substrate 21 facing the front surface side of the semiconductor substrate 31. That is, the third substrate 30 is bonded to the second substrate 20 in a face-to-face manner.

Note that FIG. 22 illustrates a case where the amplification transistor AMP provided on the second substrate 20 has a normal gate structure (for example, in FIG. 21, a structure in which the gate electrode AG only includes the first portion 81 parallel to the front surface 211a of the semiconductor layer 211) instead of the FD SOI Fin structure, but this is merely an example. Also in FIG. 22, the amplification transistor AMP may have the FD SOI Fin structure.

### Other Embodiments

As described above, the present disclosure is described according to the embodiments and modifications thereof, but it should not be understood that the description and drawings forming a part of this disclosure limit the present disclosure. Various alternative embodiments, examples, and operation techniques will be apparent to those skilled in the art from this disclosure. For example, in the first to third embodiments described above, the case where the present technology is applied to the imaging device has been described, but the present disclosure is not limited thereto. The present technology may be applied to a semiconductor device other than the imaging device, for example, a liquid crystal display, an organic EL display (organic LED display), a large scale integration (LSI), or the like. It is a matter of course that the present technology includes various embodiments and the like not described herein. At least one of various omissions, substitutions, or changes of the components may be made without departing from the gist of the above-described embodiments and modifications. Furthermore, the effect described in the present description is illustrative only; the effect is not limited thereto and there may also be another effect.

### Application Example to Mobile Body

The technology according to the present disclosure (the present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

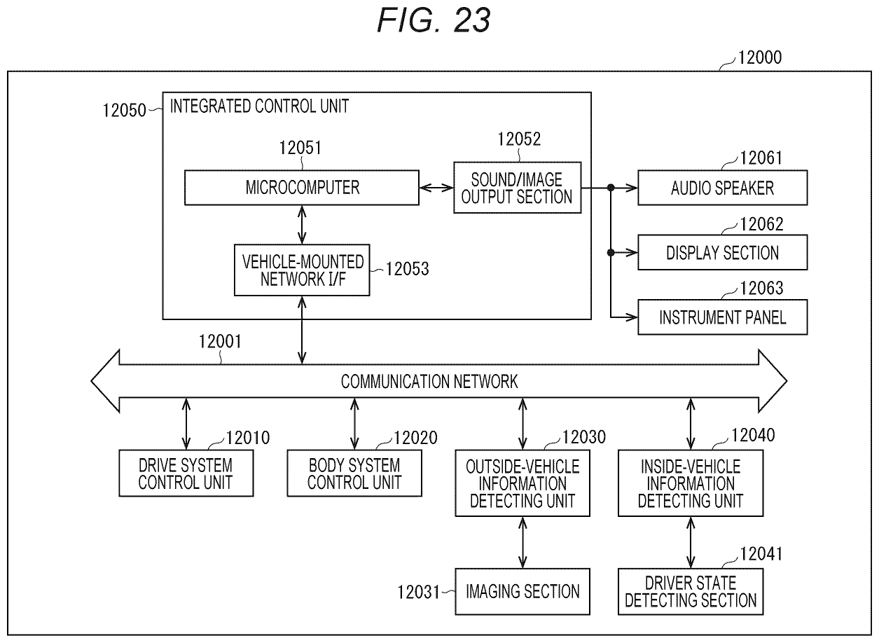

FIG. 23 is a block diagram illustrating a schematic configuration example of a vehicle control system which is an example of a mobile body control system to which the technology of the present disclosure can be applied.

The vehicle control system 12000 includes a plurality of electronic control units connected to each other via a communication network 12001. In the example illustrated in FIG. 23, the vehicle control system 12000 includes a drive system control unit 12010, a body system control unit 12020, an outside-vehicle information detecting unit 12030, an inside-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The drive system control unit 12010 controls the operation of devices related to the drive system of the vehicle in accordance with various programs. For example, the drive system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various devices mounted on a vehicle body in accordance with various programs. For example, the body system control unit 12020 functions as a control device for a keyless entry system, a smart key system, a power window device, or various lamps such as a headlamp, a back lamp, a brake lamp, a turn indicator, or a fog lamp. In this case, a radio wave transmitted from a portable device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The inside-vehicle information detecting unit 12040 detects information about the inside of the vehicle. The inside-vehicle information detecting unit 12040 is, for example, connected with a driver state detecting section 12041 that detects the state of a driver. The driver state detecting section 12041 includes, for example, a camera that captures an image of the driver, and the inside-vehicle information detecting unit 12040 may calculate the degree of fatigue or the degree of concentration of the driver or may determine whether or not the driver is dozing off on the basis of the detection information input from the driver state detecting section 12041.

The microcomputer 12051 can calculate a control target value for the driving force generating device, the steering mechanism, or the braking device on the basis of the information about the inside or outside of the vehicle which information is obtained by the outside-vehicle information detecting unit 12030 or the inside-vehicle information detecting unit 12040, and output a control command to the drive system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 can perform cooperative control intended for automated driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the inside-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

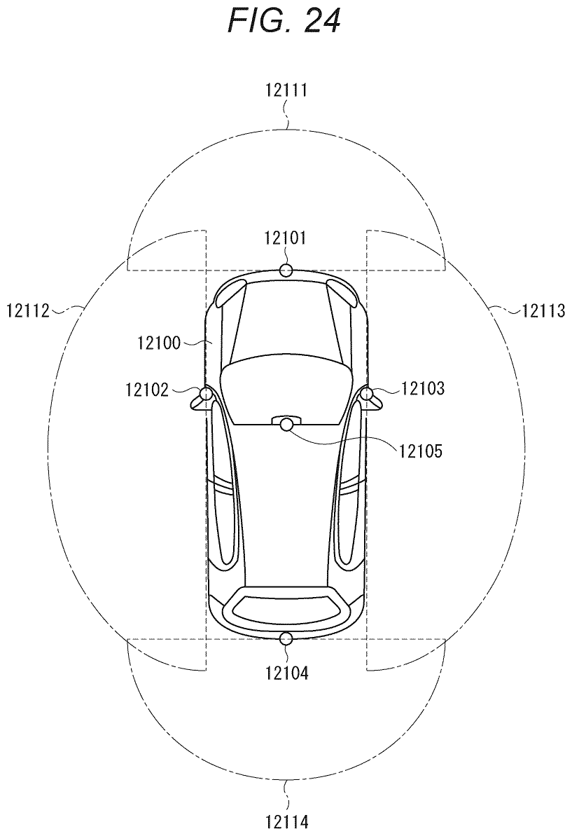

FIG. 24 is a view illustrating an example of the installation position of the imaging section 12031.

In FIG. 24, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 24 illustrates an example of imaging ranges of the imaging sections 12101 to 12104. An imaging range 12111 represents the imaging range of the imaging section 12101 provided to the front nose, imaging ranges 12112 and 12113 respectively represent the imaging ranges of the imaging sections 12102 and 12103 provided to the sideview mirrors, and an imaging range 12114 represents the imaging range of the imaging section 12104 provided on the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle, and in a situation in which the collision risk is equal to or higher than a set value and there is thus a possibility of collision, the microcomputer 12051 can output a warning to the driver via the audio speaker 12061 or the display section 12062 and perform forced deceleration or avoidance steering via the drive system control unit 12010 to perform driving assistance for collision avoidance.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such pedestrian recognition is, for example, performed by a procedure of extracting feature points in the imaged captured by the imaging sections 12101 to 12104 as infrared cameras and a procedure of determining whether or not it is a pedestrian by performing pattern matching processing on a series of feature points representing a contour of an object. When the microcomputer 12051 determines that there is a pedestrian in the taken images of the imaging sections 12101 to 12104 and recognizes the pedestrian, the sound/image output section 12052 controls the display section 12062 so that a rectangular contour for emphasis is displayed in a superimposed manner on the recognized pedestrian. Furthermore, the sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 of the configurations described above. Specifically, the imaging devices 1, 1A, 1B, and 1C according to the above-described embodiment and the modifications thereof can be applied to the imaging section 12031. By applying the technology according to the present disclosure to the imaging section 12031, it is possible to suppress deterioration of characteristics of the transistors included in the imaging section 12031 due to electromagnetic interference, and thus it is possible to obtain a more easily viewable captured image.

### Application Example to Endoscopic Surgery System

The technology according to the present disclosure (the present technology) can be applied to various products. For example, the technology according to the present disclosure may be applied to an endoscopic surgery system.

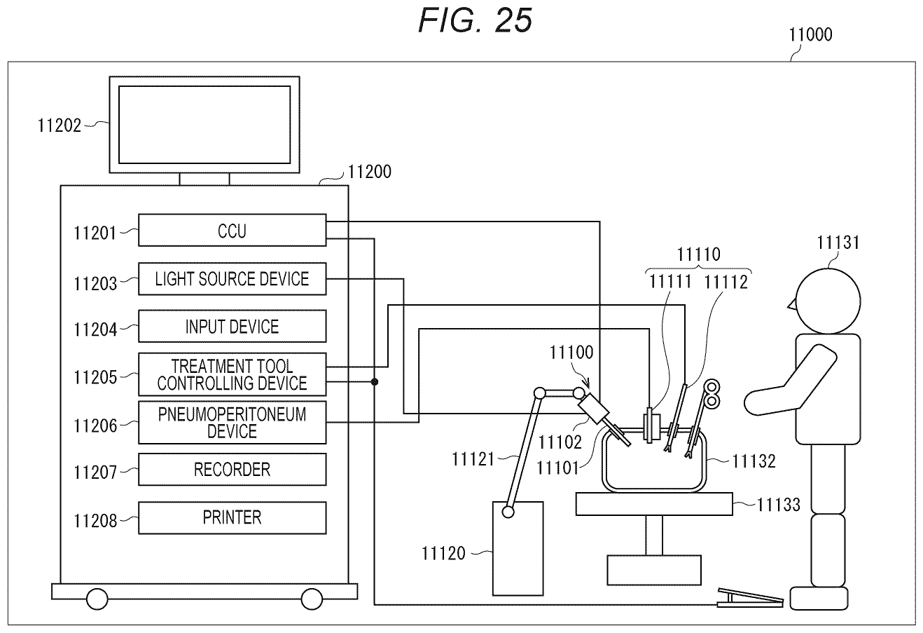

FIG. 25 is a diagram illustrating an example of a schematic configuration of an endoscopic surgery system to which the technology according to the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As illustrated, the endoscopic surgery system 11000 includes an endoscope 11100, other surgical tools 11110 such as a pneumoperitoneum tube 11111 and an energy treatment tool 11112, a supporting arm device 11120 which supports the endoscope 11100 thereon, and a cart 11200 on which various device for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example illustrated, the endoscope 11100 is illustrated which is included as a rigid endoscope having the lens barrel 11101 of the hard type, but the endoscope 11100 may otherwise be included as a so-called flexible endoscope having a lens barrel of a flexible type.

The lens barrel 11101 has, at a distal end thereof, an opening in which an objective lens is fitted. A light source device 11203 is connected to the endoscope 11100 and light generated by the light source device 11203 is guided to the distal end of the lens barrel by a light guide extending inside the lens barrel 11101, and applied to an observation target in the body cavity of the patient 11132 via the objective lens. It is to be noted that the endoscope 11100 may be a forward-viewing endoscope or may be an oblique-viewing endoscope or a side-viewing endoscope.

An optical system and an imaging element are provided in the inside of the camera head 11102 so that reflected light (observation light) from the observation target is condensed on the imaging element by the optical system. The observation light is photoelectrically converted by the imaging element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display device 11202. Moreover, the CCU 11201 receives an image signal from the camera head 11102 and performs, for the image signal, various image processes for displaying an image based on the image signal such as, for example, a development process (demosaic process).

The display device 11202 displays thereon an image based on an image signal, for which the image processes have been performed by the CCU 11201, under the control of the CCU 11201.

The light source device 11203 includes a light source such as a light emitting diode (LED), for example, and supplies irradiation light for imaging a surgical region to the endoscope 11100.

An input device 11204 is an input interface for the endoscopic surgery system 11000. The user may input various types of information and instructions to the endoscopic surgery system 11000 via the input device 11204. For example, the user would input an instruction or a like to change an imaging condition (type of irradiation light, magnification, focal distance or the like) by the endoscope 11100.

A treatment tool controlling device 11205 controls driving of the energy treatment tool 11112 for cautery or incision of a tissue, sealing of a blood vessel or the like. A pneumoperitoneum device 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is a device capable of recording various types of information related to surgery. A printer 11208 is a device capable of printing various types of information relating to surgery in various forms such as text, images, and graphs.

It is to be noted that the light source device 11203 which supplies irradiation light when a surgical region is to be imaged to the endoscope 11100 may include a white light source which includes, for example, an LED, a laser light source or a combination of them. In a case where a white light source includes a combination of red, green, and blue (RGB) laser light sources, since the output intensity and the output timing can be controlled with a high degree of accuracy for each color (each wavelength), adjustment of the white balance of a captured image can be performed by the light source device 11203. Furthermore, in this case, it is also possible to capture an image corresponding to each of RGB in a time division manner by irradiating the observation target with laser light from each of the RGB laser light sources in a time-division manner, and controlling driving of the imaging element of the camera head 11102 in synchronization with the irradiation timing. According to this method, a color image can be obtained even if color filters are not provided for the imaging element.

Furthermore, driving of the light source device 11203 may be controlled so as to change the intensity of output light at every predetermined time interval. By controlling driving of the imaging element of the camera head 11102 in synchronism with the timing of the change of the intensity of light to acquire images time-divisionally and synthesizing the images, an image of a high dynamic range free from underexposed blocked up shadows and overexposed highlights can be created.

Furthermore, the light source device 11203 may be configured to be able to supply light having a predetermined wavelength band corresponding to special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source device 11203 can be configured to supply such narrow-band light and/or excitation light suitable for special light observation as described above.

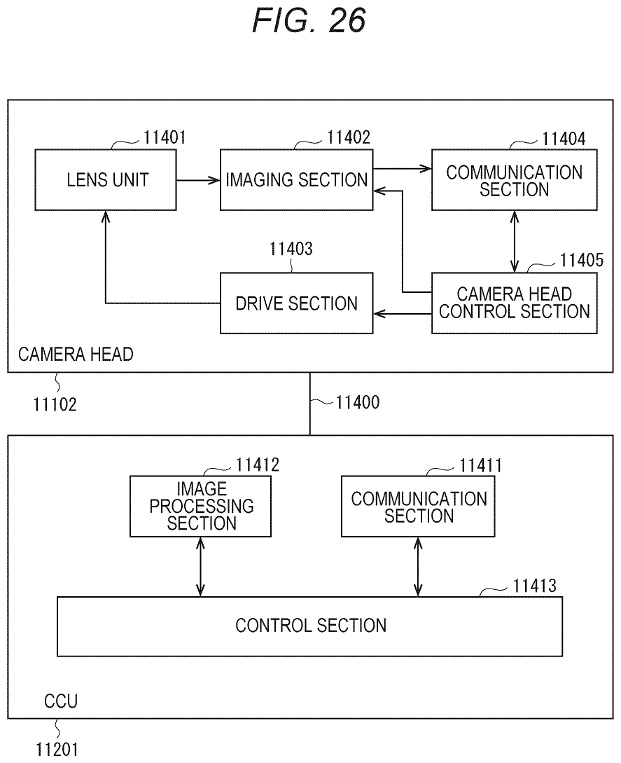

FIG. 26 is a block diagram illustrating an example of a functional configuration of the camera head 11102 and the CCU 11201 illustrated in FIG. 25.

The camera head 11102 includes a lens unit 11401, an imaging section 11402, a drive section 11403, a communication section 11404, and a camera head control section 11405. The CCU 11201 includes a communication section 11411, an image processing section 11412 and a control section 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The imaging section 11402 includes an imaging element. The number of imaging elements which is included by the imaging section 11402 may be one (single-plate type) or a plural number (multi-plate type). In a case where the imaging section 11402 is configured as that of the multi-plate type, for example, image signals corresponding to respective R, G and B are generated by the imaging elements, and the image signals may be synthesized to obtain a color image. Alternatively, the imaging section 11402 may include a pair of imaging elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the imaging section 11402 is configured as that of stereoscopic type, a plurality of systems of lens units 11401 are provided corresponding to the individual imaging elements.

Furthermore, the imaging section 11402 may not necessarily be provided in the camera head 11102. For example, the imaging section 11402 may be provided immediately behind the objective lens in the inside of the lens barrel 11101.

The drive section 11403 includes an actuator and moves the zoom lens and the focusing lens of the lens unit 11401 by a predetermined distance along an optical axis under the control of the camera head control section 11405. Consequently, the magnification and the focal point of a captured image by the imaging section 11402 can be adjusted suitably.

The communication section 11404 includes a communication device for transmitting and receiving various types of information to and from the CCU 11201. The communication section 11404 transmits an image signal acquired from the imaging section 11402 as RAW data to the CCU 11201 through the transmission cable 11400.

Furthermore, the communication section 11404 receives a control signal for controlling driving of the camera head 11102 from the CCU 11201 and supplies the control signal to the camera head control section 11405. The control signal includes information relating to imaging conditions such as, for example, information that a frame rate of a captured image is designated, information that an exposure value upon image picking up is designated and/or information that a magnification and a focal point of a captured image are designated.

It is to be noted that the imaging conditions such as the frame rate, exposure value, magnification or focal point may be designated by the user or may be set automatically by the control section 11413 of the CCU 11201 on the basis of an acquired image signal. In the latter case, an auto exposure (AE) function, an auto focus (AF) function and an auto white balance (AWB) function are incorporated in the endoscope 11100.

The camera head control section 11405 controls driving of the camera head 11102 on the basis of a control signal from the CCU 11201 received through the communication section 11404.

The communication section 11411 includes a communication device for transmitting and receiving various types of information to and from the camera head 11102. The communication section 11411 receives an image signal transmitted thereto from the camera head 11102 through the transmission cable 11400.

Furthermore, the communication section 11411 transmits a control signal for controlling driving of the camera head 11102 to the camera head 11102. The image signal and the control signal can be transmitted by electrical communication, optical communication or the like.

The image processing section 11412 performs various image processes for an image signal in the form of RAW data transmitted thereto from the camera head 11102.

The control section 11413 performs various control related to imaging of the surgical site or the like by the endoscope 11100 and display of a captured image obtained by the imaging of the surgical site or the like. For example, the control section 11413 creates a control signal for controlling driving of the camera head 11102.

Furthermore, the control section 11413 controls, on the basis of an image signal for which image processes have been performed by the image processing section 11412, the display device 11202 to display a captured image in which the surgical region or the like is imaged. At this time, the control section 11413 may recognize various objects in the captured image using various image recognition technologies. For example, the control section 11413 can recognize a surgical tool such as forceps, a particular living body region, bleeding, mist when the energy treatment tool 11112 is used and so forth by detecting the shape, color and so forth of edges of objects included in a captured image. At the time of causing the display device 11202 to display the captured image, the control section 11413 may overlay various types of surgery assistance information on the image of the surgical site using the recognition result. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, in the illustrated example, communication is performed by wire using the transmission cable 11400, but the communication between the camera head 11102 and the CCU 11201 may be performed wirelessly.

An example of the endoscopic surgery system to which the technology according to the present disclosure can be applied has been described above. The technology according to the present disclosure can be applied to, for example, the endoscope 11100, (the imaging section 11402 of) the camera head 11102, (the image processing section 11412 of) the CCU 11201, and the like among the configurations described above. By applying the technology according to the present disclosure to the imaging section 11402, the image processing section 11412, and the like, it is possible to suppress deterioration of characteristics of transistors included in the imaging section 11402 and the image processing section 11412 due to electromagnetic interference, and thus it is possible to obtain a clearer surgical site image.

Note that an endoscopic surgery system has been described as an example herein, but the technology according to the present disclosure may be applied to a microscopic surgery system or the like, for example.

Note that the present disclosure can also have the following configurations.

(1)

An imaging device including:
a first semiconductor layer provided with a sensor pixel that performs photoelectric conversion;
a second semiconductor layer disposed on one surface side of the first semiconductor layer and provided with a pixel transistor for outputting a pixel signal based on a charge output from the sensor pixel;
an insulating layer disposed between the first semiconductor layer and the second semiconductor layer; and
a conductor layer disposed between the sensor pixel and the pixel transistor in the insulating layer, in which
a potential of the conductor layer is fixed to a reference potential.
   (2)

The imaging device according to (1) above, in which the conductor layer is disposed between the sensor pixel and at least a channel region of the pixel transistor.

(3)

The imaging device according to (1) or (2) above, in which
the sensor pixel includes:
a photoelectric conversion element provided in the first semiconductor layer;
a floating diffusion provided in the first semiconductor layer; and
a transfer transistor that transfers a charge generated in the photoelectric conversion element to the floating diffusion, and
the conductor layer is disposed between the photoelectric conversion element and the pixel transistor.
   (4)

The imaging device according to (3) above, in which
the sensor pixel includes
a wiring layer connected to a gate electrode of the transfer transistor, and
the wiring layer is disposed between the photoelectric conversion element and the conductor layer.
   (5)

The imaging device according to any one of (1) to (4) above, in which
the sensor pixel includes:
a well contact region provided in the first semiconductor layer; and
a through wiring that is in contact with the well contact region and penetrates the insulating layer in a thickness direction, and
the conductor layer is in contact with the through wiring.
   (6)

The imaging device according to (5) above, in which the conductor layer is in contact with a side surface of the through wiring.

(7)

The imaging device according to any one of (1) to (6) above, in which
the first semiconductor layer includes a plurality of the sensor pixels, and
the conductor layer is continuously provided from one sensor pixel to another pixel among the plurality of sensor pixels.
   (8)

The imaging device according to (7) above, in which a shape of the conductor layer in plan view is a linear shape extending in one direction or a grid frame shape.

(9)

The imaging device according to any one of (1) to (8) above, in which the pixel transistor is any one or more of an amplification transistor, a selection transistor, a reset transistor, and a switch transistor.

(10)

The imaging device according to any one of (1) to (9) above, in which the pixel transistor has an FD SOI Fin structure.

(11)

The imaging device according to (10) above, in which
a gate electrode of the pixel transistor having the FD SOI Fin structure includes:
a first portion facing an upper surface of the second semiconductor layer via a gate insulating film;
a second portion facing a first side surface of the second semiconductor layer via the gate insulating film; and
a third portion facing a second side surface of the second semiconductor layer via the gate insulating film, and
a lower surface of the second semiconductor layer, the second portion, and the third portion are in contact with a bottom insulating film.
   (12)

The imaging device according to any one of (1) to (10) above, in which the conductor layer includes a polycrystalline silicon film.

(13)

A semiconductor device including:
a first semiconductor layer;
a second semiconductor layer disposed on one surface side of the first semiconductor layer and provided with a transistor;
an insulating layer disposed between the first semiconductor layer and the second semiconductor layer; and
a conductor layer disposed between the first semiconductor layer and the transistor in the insulating layer, in which
a potential of the conductor layer is fixed to a reference potential.

### REFERENCE SIGNS LIST

1, 1A, 1B, 1C Imaging device
10 First substrate
11, 21, 31 Semiconductor substrate
11a Front surface
12 Sensor pixel
13 Pixel region
14 Well region
15 Well contact region
16 Third insulating film
17 First wiring layer
18 Second wiring layer
20 Second substrate
22 Readout circuit
23 Pixel drive line
24 Vertical signal line
25 Third substrate
32 Logic circuit
33 Vertical drive circuit
34 Column signal processing circuit
35 Horizontal drive circuit
36 System control circuit
40 Color filter
42 Gate insulating film
43 Fourth insulating film
45 Fifth insulating film
46 Sixth insulating film
50 Light receiving lens
51, 52 Through wiring
53 Third wiring layer
56, 62 Wiring layer
57, 63 Interlayer insulating film
58, 64 Pad electrode
61 Source/drain region
81 First portion
82 Second portion
83 Third portion
91 Source region
92 Drain region
161 First insulating film
162 Second insulating film
163 Third insulating film
164 Fourth insulating film
181 First straight line portion
182 Second straight line portion
211 Semiconductor layer
521 First portion
522 Second portion
11000 Endoscopic surgery system
11100 Endoscope
11101 Lens barrel
11102 Camera head
11110 Surgical tool
11111 Pneumoperitoneum tube
11112 Energy treatment tool
11120 Support arm device
11131 Surgeon (medical doctor)
11131 Surgeon
11132 Patient
11133 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402 Imaging section
11403 Drive section
11404 Communication section
11405 Camera head control section
11411 Communication section
11412 Image processing section
11413 Control section
12000 Vehicle control system
12001 Communication network
12010 Drive system control unit
12020 Body system control unit
12030 Outside-vehicle information detecting unit
12031 Imaging section
12040 Inside-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 Imaging section
12102 Imaging section
12103 Imaging section
12104 Imaging section
12105 Imaging section
12111 Imaging range
12112 Imaging range
12113 Imaging range
12114 Imaging range
AG Gate electrode
AMP Amplification transistor
FD Floating diffusion
FDG Switch transistor
PD Photodiode
RST Reset transistor
SEL Selection transistor
SG Gate electrode
TG Transfer gate
TR Transfer transistor
VDD Power supply line
Vout Output voltage
Z11, Z12, Z13, Z21, Z22, Z23 Horizontal plane

1. An imaging device comprising:
a first semiconductor layer provided with a sensor pixel that performs photoelectric conversion;
a second semiconductor layer disposed on one surface side of the first semiconductor layer and provided with a pixel transistor for outputting a pixel signal based on a charge output from the sensor pixel;
an insulating layer disposed between the first semiconductor layer and the second semiconductor layer; and
a conductor layer disposed between the sensor pixel and the pixel transistor in the insulating layer, wherein
a potential of the conductor layer is fixed to a reference potential.

2. The imaging device according to claim 1, wherein the conductor layer is disposed between the sensor pixel and at least a channel region of the pixel transistor.

3. The imaging device according to claim 1, wherein
the sensor pixel includes:
a photoelectric conversion element provided in the first semiconductor layer;
a floating diffusion provided in the first semiconductor layer; and
a transfer transistor that transfers a charge generated in the photoelectric conversion element to the floating diffusion, and
the conductor layer is disposed between the photoelectric conversion element and the pixel transistor.

4. The imaging device according to claim 3, wherein
the sensor pixel includes
a wiring layer connected to a gate electrode of the transfer transistor, and
the wiring layer is disposed between the photoelectric conversion element and the conductor layer.

5. The imaging device according to claim 1, wherein
the sensor pixel includes:
a well contact region provided in the first semiconductor layer; and
a through wiring that is in contact with the well contact region and penetrates the insulating layer in a thickness direction, and
the conductor layer is in contact with the through wiring.

6. The imaging device according to claim 5, wherein the conductor layer is in contact with a side surface of the through wiring.

7. The imaging device according to claim 1, wherein
the first semiconductor layer includes a plurality of the sensor pixels, and
the conductor layer is continuously provided from one sensor pixel to another pixel among the plurality of sensor pixels.

8. The imaging device according to claim 7, wherein a shape of the conductor layer in plan view is a linear shape extending in one direction or a grid frame shape.

9. The imaging device according to claim 1, wherein the pixel transistor is any one or more of an amplification transistor, a selection transistor, a reset transistor, and a switch transistor.

10. The imaging device according to claim 1, wherein the pixel transistor has an FD SOI Fin structure.

11. The imaging device according to claim 10, wherein
a gate electrode of the pixel transistor having the FD SOI Fin structure includes:
a first portion facing an upper surface of the second semiconductor layer via a gate insulating film;
a second portion facing a first side surface of the second semiconductor layer via the gate insulating film; and
a third portion facing a second side surface of the second semiconductor layer via the gate insulating film, and
a lower surface of the second semiconductor layer, the second portion, and the third portion are in contact with a bottom insulating film.

12. The imaging device according to claim 1, wherein the conductor layer includes a polycrystalline silicon film.

13. A semiconductor device comprising:
a first semiconductor layer;
a second semiconductor layer disposed on one surface side of the first semiconductor layer and provided with a transistor;
an insulating layer disposed between the first semiconductor layer and the second semiconductor layer; and
a conductor layer disposed between the first semiconductor layer and the transistor in the insulating layer, wherein
a potential of the conductor layer is fixed to a reference potential.
